(19) United States
(12) Patent Application Publication
(10) Pub. No.: US 2024/0353182 A1
(43) Pub. Date: Oct. 24, 2024

(54) VAPOR CHAMBER, WICK SHEET FOR VAPOR CHAMBER, AND ELECTRONIC APPARATUS

(71) Applicant: DAI NIPPON PRINTING CO., LTD., Tokyo-to (JP)

(72) Inventors: Kazunori ODA, Tokyo-to (JP); Shinichiro TAKAHASHI, Tokyo-to (JP); Takayuki OTA, Tokyo-to (JP); Makoto YAMAKI, Tokyo-to (JP); Youji KOZURU, Tokyo-to (JP)

(73) Assignee: DAI NIPPON PRINTING CO., LTD., Tokyo-to (JP)

(21) Appl. No.: 18/291,057

(22) PCT Filed: Jul. 20, 2022
(86) PCT No.: PCT/JP2022/028218

§ 371 Date: Jan. 22, 2024

(30) Foreign Application Priority Data
Jul. 20, 2021 (JP) 2021-119907

(51) Int. Cl. F28D 15/04; H05K 7/20

(52) U.S. Cl. CPC F28D 15/04; H05K 7/20336

(57) ABSTRACT

A wick sheet for a vapor chamber includes a plurality of vapor passages through which vapor of a working fluid passes, and a plurality of liquid channels through which liquid of the working fluid passes. The plurality of liquid channels progressively separates from one side toward the other side in extension directions of the liquid channels. The liquid channel is branched to a plurality of first branched liquid channels at a first branched part located midway in the extension direction of the liquid channel.

### TECHNICAL FIELD

The present disclosure relates to a vapor chamber, a wick sheet for a vapor chamber, and an electronic apparatus.

### BACKGROUND ART

Devices accompanied by heat generation, used in mobile terminals and the like, such as portable terminals and tablet terminals, are cooled by heat dissipation members, such as heat pipes. Examples of the devices accompanied by heat generation include central processing units (CPUs), light emitting diodes (LEDs), and power semiconductors. In recent years, for the purpose of providing thinner mobile terminals and the like, low-profile heat dissipation members are also desired. For this reason, development of vapor chambers that can lead to a further lower profile than heat pipes has been proceeding. A working fluid is filled in vapor chambers. The working fluid absorbs and dissipates the heat of devices to cool the devices. For example, PTL 1 describes a sheet heat pipe in which two or more metal foil sheets are laminated.

More specifically, a working fluid in the vapor chamber receives heat from a device at a part proximate to the device (vaporizing portion) to vaporize into vapor (working vapor). The working vapor diffuses in a direction away from the vaporizing portion in a vapor channel to be cooled and condensed into liquid. A liquid channel serving as a capillary structure (wick) is provided in the vapor chamber. A working fluid (working liquid) condensed into liquid enters the liquid channel from the vapor channel, flows through the liquid channel, and is transferred toward the vaporizing portion. Then, the working liquid receives heat at the vaporizing portion again to vaporize. In this way, the working fluid transfers heat of the device by circulating in the vapor chamber while repeating a phase change, that is, vaporization and condensation, thus enhancing heat dissipation efficiency.

### CITATION LIST

### Patent Literature

PTL 1: Japanese Unexamined Patent Application Publication No. 2016-017702

The present embodiment provides a vapor chamber, a wick sheet for a vapor chamber, and an electronic apparatus, capable of causing a working vapor to go around in a wide region in the vapor chamber.

### SUMMARY OF INVENTION

A wick sheet according to the present embodiment is a wick sheet for a vapor chamber. The wick sheet includes a plurality of vapor passages through which vapor of a working fluid passes, and a plurality of liquid channels through which liquid of the working fluid passes. The plurality of liquid channels progressively separates from each other from one side toward the other side in extension directions of the liquid channels. The liquid channel is branched to a plurality of first branched liquid channels at a first branched part located midway in the extension direction of the liquid channel.

### BRIEF DESCRIPTION OF DRAWINGS

FIG. 1 is a schematic perspective view illustrating an electronic apparatus according to an embodiment of the present disclosure.

FIG. 2 is a top view showing a vapor chamber according to the embodiment of the present disclosure.

FIG. 3 is a sectional view of the vapor chamber, taken along the line III-III in FIG. 2.

FIG. 4 is a top view of a wick sheet of FIG. 3.

FIG. 5 is a bottom view of the wick sheet of FIG. 3.

FIG. 6 is a partially enlarged top view of a liquid channel shown in FIG. 4.

FIGS. 7(a) to 7(c) are views illustrating a manufacturing method for a vapor chamber according to the embodiment.

FIG. 8 is a top view showing a wick sheet according to a first modification.

FIG. 9 is a top view showing a wick sheet according to a second modification.

FIG. 10 is a top view showing a wick sheet according to a third modification.

FIG. 11 is a view showing a wick sheet according to a fourth modification.

FIG. 12 is a partially enlarged top view showing a liquid channel according to a fifth modification.

FIG. 13 is a partially enlarged top view showing a liquid channel according to a sixth modification.

FIG. 14 is a partially enlarged top view showing a wick sheet according to a seventh modification.

FIG. 15 is a partially enlarged view of FIG. 14 (an enlarged view of portion XV in FIG. 14).

FIGS. 16(a) and 16(b) are partially sectional views of FIG. 15 (a sectional view taken along the line XVIA-XVIA and a sectional view taken along the line XVIB-XVIB in FIG. 15).

FIG. 17 is a top view showing the wick sheet according to the seventh modification.

FIG. 18 is a top view showing a wick sheet according to an eighth modification.

FIG. 19 is a partially enlarged view of FIG. 18 (an enlarged view of portion XIX in FIG. 18).

FIG. 20 is a top view showing a wick sheet according to a ninth modification.

FIG. 21 is a top view showing a wick sheet according to the ninth modification.

FIG. 22 is a top view showing a wick sheet according to a tenth modification.

FIG. 23 is a top view showing a wick sheet according to the tenth modification.

FIG. 24 is a top view showing a wick sheet according to the tenth modification.

FIG. 25 is a top view showing a wick sheet according to an eleventh modification.

### DESCRIPTION OF EMBODIMENTS

An embodiment of the present disclosure relates to the following [1] to [21].
[1] A wick sheet for a vapor chamber, the wick sheet including: a plurality of vapor passages through which vapor of a working fluid passes; and a plurality of liquid channels through which liquid of the working fluid passes, wherein the plurality of liquid channels progressively separates from each other from one side toward the other side in extension directions of the liquid channels, and the liquid channel is branched to a plurality of first branched liquid channels at a first branched part located midway in the extension direction of the liquid channel.
[2] The wick sheet according to [1], wherein the first branched liquid channel is branched to a plurality of second branched liquid channels at a second branched part located midway in an extension direction of the first branched liquid channel.
[3] The wick sheet according to [2], wherein the second branched liquid channel is branched to a plurality of third branched liquid channels at a third branched part located midway in an extension direction of the second branched liquid channel, and a length of the first branched liquid channel in the extension direction from the first branched part to the second branched part is shorter than a length of the second branched liquid channel in the extension direction from the second branched part to the third branched part.
[4] The wick sheet according to any one of [1] to [3], wherein an additional vapor passage is present between adjacent two of the first branched liquid channels, a width of the vapor passage is constant over a region in an extension direction of the vapor passage, and a width of the additional vapor passage is gradually widened from one side toward the other side in an extension direction of the additional vapor passage.
[5] The wick sheet according to any one of [1] to [4], wherein an additional vapor passage is present between adjacent two of the first branched liquid channels, the vapor passage and the additional vapor passage or the additional vapor passages are coupled to each other by a coupling portion thinner in thickness than the liquid channel.
[6] A wick sheet for a vapor chamber, the wick sheet including: a plurality of vapor passages through which vapor of a working fluid passes; and a plurality of liquid channels through which liquid of the working fluid passes, wherein the plurality of vapor passages progressively separates from each other from one side toward the other side in extension directions of the vapor passages, and the vapor passage is branched to a plurality of first branched vapor passages at a fourth branched part located midway in the extension direction of the vapor passage.
[7] The wick sheet according to [6], wherein the first branched vapor passage is branched to a plurality of second branched vapor passages at a fifth branched part located midway in an extension direction of the first branched vapor passage.
[8] The wick sheet according to [7], wherein the second branched vapor passage is branched to a plurality of third branched vapor passages at a sixth branched part located midway in an extension direction of the second branched vapor passage, and a length of the first branched vapor passage in the extension direction from the fourth branched part to the fifth branched part is shorter than a length of the second branched vapor passage in the extension direction from the fifth branched part to the sixth branched part.
[9] A wick sheet for a vapor chamber, the vapor chamber including: a plurality of vapor passages through which vapor of a working fluid passes; and a plurality of liquid channels through which liquid of the working fluid passes, wherein a width of the liquid channel gradually widens from one side toward the other side in an extension direction of the liquid channel, the liquid channel has a plurality of liquid channel main stream grooves disposed so as to run side by side to each other, a protrusion array is provided between adjacent two of the liquid channel main stream grooves, and each protrusion array has a plurality of protrusions, and the number of the protrusion arrays increases as the width of the liquid channel widens.
[10] A wick sheet for a vapor chamber, the wick sheet including: a plurality of vapor passages through which vapor of a working fluid passes; and a plurality of liquid channels through which liquid of the working fluid passes, wherein the width of the vapor passage changes at a width change part midway in the extension direction of the vapor passage, and the width of the vapor passage is uniform on one side of the width change part and gradually widens on the other side of the width change part in the extension direction of the vapor passage.
[11] A wick sheet for a vapor chamber, the wick sheet including: a plurality of vapor passages through which vapor of a working fluid passes; and a plurality of liquid channels through which liquid of the working fluid passes, wherein there are a region in which the vapor passages and the liquid channels radially extend and a region in which the vapor passages and the liquid channels linearly extend in the same direction, and, in the region in which the vapor passages and the liquid channels radially extend, a width of the vapor passage gradually widens from one side toward the other side in an extension direction of the vapor passage or a width of the liquid channel gradually widens from one side toward the other side in an extension direction of the liquid channel.
[12] A wick sheet for a vapor chamber, the wick sheet including: a plurality of vapor passages through which vapor of a working fluid passes; and a plurality of liquid channels through which liquid of the working fluid passes, wherein there are a region in which the vapor passages and the liquid channels extend so as to be curved or bent and a region in which the vapor passages and the liquid channels linearly extend in the same direction, and, in the region in which the vapor passages and the liquid channels extend so as to be curved or bent, a width of the vapor passage gradually widens from one side toward the other side in an extension direction of the vapor passage or a width of the liquid channel gradually widens from one side toward the other side in an extension direction of the liquid channel.
[13] A wick sheet for a vapor chamber, the wick sheet including: a plurality of vapor passages through which vapor of a working fluid passes; and a plurality of liquid channels through which liquid of the working fluid passes, wherein widths of the plurality of vapor passages are different from each other, and the width of the vapor passage of which a length in an extension direction is long is wider than the width of the vapor passage of which a length in an extension direction is short.
[14] The wick sheet according to [13], wherein the width of the vapor passage changes at a width change part midway in the extension direction of the vapor passage, and the width of the vapor passage is uniform on each of one side of the width change part and the other side of the width change part in the extension direction of the vapor passage.
[15] The wick sheet according to or [14], wherein the lengths of the plurality of vapor passages in the respectively extension directions are different from each other, and the width of the vapor passage widens as the length of the vapor passage in the extension direction increases.
[16] A wick sheet for a vapor chamber, the wick sheet including: a first main body surface; a second main body surface on an opposite side to the first main body surface; a plurality of vapor passages through which vapor of a working fluid passes; and a plurality of liquid channels through which liquid of the working fluid passes, wherein a width of the vapor passage at the first main body surface or a width of the vapor passage at the second main body surface changes at a width change part midway in an extension direction of the vapor passage, and the width of the vapor passage at the first main body surface or the width of the vapor passage at the second main body surface is uniform on one side of the width change part and gradually widens on the other side of the width change part in the extension direction of the vapor passage.
[17] A wick sheet for a vapor chamber, the wick sheet including: a first main body surface; a second main body surface on an opposite side to the first main body surface; a plurality of vapor passages through which vapor of a working fluid passes; and a plurality of liquid channels through which liquid of the working fluid passes, wherein there are a region in which the vapor passages and the liquid channels radially extend and a region in which the vapor passages and the liquid channels linearly extend in the same direction, and, in the region in which the vapor passages and the liquid channels radially extend, a width of the vapor passage at the first main body surface or the second main body surface gradually widens from one side toward the other side in an extension direction of the vapor passage or a width of the liquid channel at the first main body surface or the second main body surface gradually widens from one side toward the other side in an extension direction of the liquid channel.
[18] A wick sheet for a vapor chamber, the wick sheet including: a first main body surface; a second main body surface on an opposite side to the first main body surface; a plurality of vapor passages through which vapor of a working fluid passes; and a plurality of liquid channels through which liquid of the working fluid passes, wherein there are a region in which the vapor passages and the liquid channels extend so as to be curved or bent and a region in which the vapor passages and the liquid channels linearly extend in the same direction, and, in the region in which the vapor passages and the liquid channels extend so as to be curved or bent, a width of the vapor passage at the first main body surface or the second main body surface gradually widens from one side toward the other side in an extension direction of the vapor passage or a width of the liquid channel at the first main body surface or the second main body surface gradually widens from one side toward the other side in an extension direction of the liquid channel.
[19] A wick sheet for a vapor chamber, the wick sheet including: a first main body surface; a second main body surface on an opposite side to the first main body surface; a plurality of vapor passages through which vapor of a working fluid passes; and a plurality of liquid channels through which liquid of the working fluid passes, wherein widths of the plurality of vapor passages at the first main body surface are different from each other or widths of the plurality of vapor passages at the second main body surface are different from each other, and the width of the vapor passage at the first main body surface, of which a length in an extension direction is long, is wider than the width of the vapor passage at the first main body surface, of which the length in an extension direction is short, or the width of the vapor passage at the second main body surface, of which a length in an extension direction is long, is wider than the width of the vapor passage at the second main body surface, of which the length in an extension direction is short.
[20] A vapor chamber filled with a working fluid, the vapor chamber including: at least one sheet; and the wick sheet according to any one of [1] to [19], laminated on the sheet.
[21] An electronic apparatus including: a housing; a heat source accommodated in the housing; and the vapor chamber according to [20], being in thermal contact with the heat source.

According to the embodiment of the present disclosure, it is possible to cause working vapor to go around in a wide region in the vapor chamber.

Hereinafter, an embodiment of the present disclosure will be described with reference to the drawings. In the drawings attached to the present specification, for the sake of easiness of illustration and understanding, the scale, dimensional aspect ratio, and the like are changed or exaggerated as needed from those of real ones.

Terms, such as “parallel”, “orthogonal”, and “the same”, values of length, angle, and physical characteristics, and the like that determine shapes, geometrical conditions, physical characteristics, the degrees of them, used in the specification are not limited to strict meanings. These terms or numeric values are interpreted so as to include the range of degrees to which similar functions can be expected. Furthermore, in the drawings, for the sake of clear illustration, the shapes of a plurality of portions from which similar functions can be expected are shown regularly; however, the shapes of the portions may be different from each other without limitations to strict meanings within the range in which the functions can be expected. In the drawings, boundary lines each representing a joint surface or the like between members are indicated merely by straight lines for the sake of convenience. Boundary lines are not limited to strict straight lines. The shapes of the boundary lines can be selected within the range in which desired joint performance can be expected.

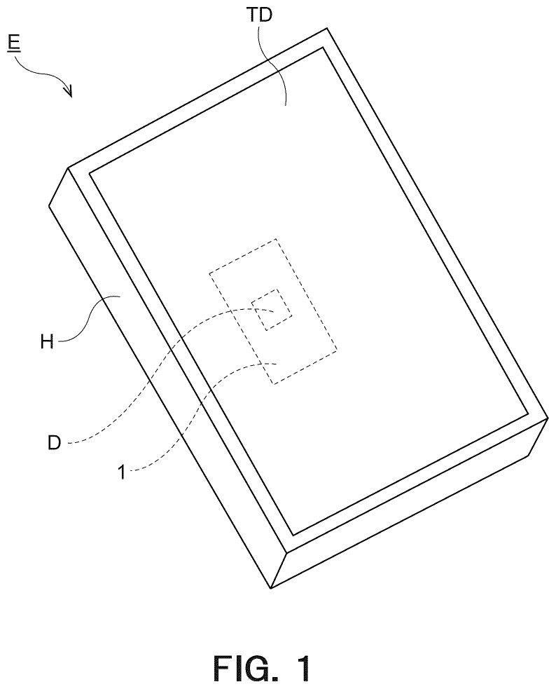

A vapor chamber, a wick sheet for a vapor chamber, and an electronic apparatus according to the present embodiment will be described with reference to FIGS. 1 to 6. A vapor chamber 1 according to the present embodiment is a device mounted on an electronic apparatus E to cool a device D serving as a heat source (heating element) accommodated in the electronic apparatus E. Examples of the device D include electronic devices (devices to be cooled) accompanied by heat generation, such as central processing units (CPUs), light emitting diodes (LEDs), and power semiconductors, used in mobile terminals and the like, such as portable terminals and tablet terminals.

Here, initially, the electronic apparatus E on which the vapor chamber 1 according to the present embodiment is mounted will be described by taking a tablet terminal as an example. As shown in FIG. 1, the electronic apparatus E (for example, a tablet terminal) includes a housing H, the device D accommodated in the housing H, and the vapor chamber 1. In the electronic apparatus E shown in FIG. 1, a touch panel display TD is provided on the front face of the housing H. The vapor chamber 1 is accommodated in the housing H and is disposed in thermal contact with the device D. With this configuration, the vapor chamber 1 can receive heat that is generated in the device D during use of the electronic apparatus E. The heat received by the vapor chamber 1 is released to outside the vapor chamber 1 via working fluids 2a, 2b (described later). In this way, the device D is effectively cooled. When the electronic apparatus E is a tablet terminal, the device D corresponds to a central processing unit or the like.

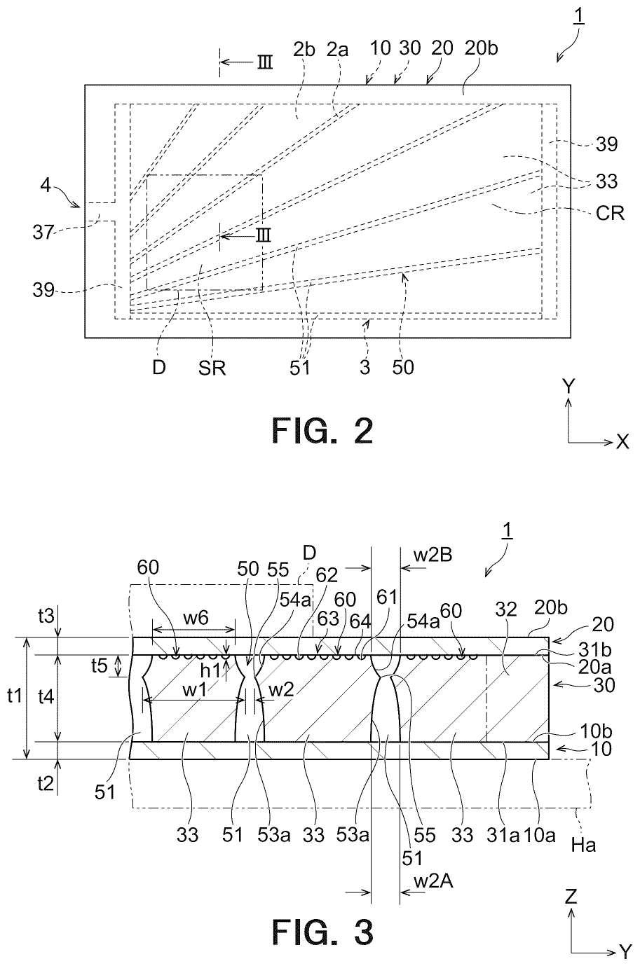

Next, the vapor chamber 1 according to the present embodiment will be described. As shown in FIGS. 2 and 3, the vapor chamber 1 has a sealed space 3 filled with the working fluids 2a, 2b. As the working fluids 2a, 2b in the sealed space 3 repeat a phase change, the vapor chamber 1 effectively cools the device D of the above-described electronic apparatus E. Examples of the working fluids 2a, 2b include pure water, ethanol, methanol, acetone, and mixed solutions of some of them. The working fluids 2a, 2b may have freezing and expansion properties. In other words, the working fluids 2a, 2b may be fluids that expand when frozen. Examples of the working fluids 2a, 2b having freezing and expansion properties include pure water and a solution obtained by adding an additive, such as alcohol, to pure water.

As shown in FIGS. 2 and 3, the vapor chamber 1 includes a lower sheet 10 (first sheet), an upper sheet 20 (second sheet), and a wick sheet for a vapor chamber (hereinafter, simply referred to as wick sheet 30). The wick sheet 30 is interposed between the lower sheet 10 and the upper sheet 20. In the vapor chamber 1 according to the present embodiment, the lower sheet 10, the wick sheet 30, and the upper sheet 20 are laminated in this order.

The vapor chamber 1 is schematically formed in a thin sheet shape. The planar shape of the vapor chamber 1 is selectable and may be a rectangular shape as shown in FIG. 2. The planar shape of the vapor chamber 1 may be, for example, a rectangular shape with one side having a length of greater than or equal to 50 mm and less than or equal to 200 mm and the other side having a length of greater than or equal to 150 mm and less than or equal to 600 mm. The planar shape of the vapor chamber 1 may be a square shape with one side having a length of greater than or equal to 70 mm and less than or equal to 300 mm. The plane dimensions of the vapor chamber 1 are selectable. In the present embodiment, in an example, an example in which the planar shape of the vapor chamber 1 is a rectangular shape having an X direction (described later) as a longitudinal direction will be described. In this case, as shown in FIG. 2, the lower sheet 10, the upper sheet 20, and the wick sheet 30 each may have a planar shape similar to that of the vapor chamber 1. The planar shape of the vapor chamber 1 is not limited to a rectangular shape and may be a selected shape, such as a circular shape, an elliptical shape, an L-shape, a T-shape, and a U-shape.

As shown in FIG. 2, the vapor chamber 1 has a heat source region SR and a condensation region CR. The heat source region SR is a region in which the device D that is a heat source is disposed and the working fluids 2a, 2b vaporize. The condensation region CR is a region in which the working fluids 2a, 2b condense.

The heat source region SR is a region that overlaps the device D that is a heat source in a plan view and is a region in which the device D is attached. The heat source region SR may be disposed in a selected place of the vapor chamber 1. In the present embodiment, the heat source region SR is formed on one side (left side in FIG. 2) of the vapor chamber 1 in the X direction. Heat from the device D is transferred to the heat source region SR, and a liquid working fluid (referred to as working liquid 2b as needed) vaporizes in the heat source region SR due to the heat. Therefore, the heat source region SR makes up a vaporization region where the working fluids 2a, 2b vaporize. Heat from the device D can be transferred not only to the region that overlaps the device D but also to around the region in a plan view. Here, a plan view is a state viewed in a direction orthogonal to a surface that the vapor chamber 1 receives heat from the device D (a second upper sheet surface 20b (described later) of the upper sheet 20) and a surface that releases the received heat (a first lower sheet surface 10a (described later) of the lower sheet 10). In other words, a plan view, for example, corresponds to a state when the vapor chamber 1 is viewed from above as shown in FIG. 2 or a state when the vapor chamber 1 is viewed from below.

The condensation region CR is a region that does not overlap the device D in a plan view and is a region where the working vapor 2a mainly releases heat to condense. The condensation region CR may also be referred to as a region located around the heat source region SR. Heat from the working vapor 2a is released to the lower sheet 10 in the condensation region CR, and the working vapor 2a is cooled in the condensation region CR to condense.

When the vapor chamber 1 is installed in a mobile terminal, an upper and lower relation can be lost depending on the posture of the mobile terminal. However, in the present embodiment, for the sake of convenience, a sheet that receives heat from the device D is referred to as the above-described upper sheet 20, and a sheet that releases the received heat is referred to as the above-described lower sheet 10. Therefore, the description will be made in a state where the lower sheet 10 is disposed on the lower side and the upper sheet 20 is disposed on the upper side.

As shown in FIG. 3, the lower sheet 10 has a first lower sheet surface 10a and a second lower sheet surface 10b. The first lower sheet surface 10a is located on the opposite side to the wick sheet 30. The second lower sheet surface 10b is located on the opposite side to the first lower sheet surface 10a (that is, the wick sheet 30 side). The lower sheet 10 may be formed entirely in a flat shape. The lower sheet 10 may entirely have a constant thickness. A housing member Ha that is part of the housing of the mobile terminal or the like is attached to the first lower sheet surface 10a. The whole of the first lower sheet surface 10a may be covered with the housing member Ha.

As shown in FIG. 3, the upper sheet 20 has a first upper sheet surface 20a and a second upper sheet surface 20b. The first upper sheet surface 20a is provided on the wick sheet 30 side. The second upper sheet surface 20b is located on the opposite side to the first upper sheet surface 20a. The upper sheet 20 may be formed entirely in a flat shape. The upper sheet 20 may entirely have a constant thickness. The above-described device D is attached to the second upper sheet surface 20b.

As shown in FIG. 3, the wick sheet 30 includes a vapor channel 50 and liquid channels 60 disposed adjacent to the vapor channel 50. The wick sheet 30 has a first main body surface 31a and a second main body surface 31b on the opposite side to the first main body surface 31a. The first main body surface 31a is disposed on the lower sheet 10 side. The second main body surface 31b is disposed on the upper sheet 20 side.

The second lower sheet surface 10b of the lower sheet 10 and the first main body surface 31a of the wick sheet 30 may be permanently joined with each other by diffusion joining. Similarly, the first upper sheet surface 20a of the upper sheet 20 and the second main body surface 31b of the wick sheet 30 may be permanently joined with each other by diffusion joining. The lower sheet 10, the upper sheet 20, and the wick sheet 30 may be joined not by diffusion joining but by another method, such as brazing, as long as they can be permanently joined. The term “permanently joined” is not limited to a strict meaning. The term “permanently joined” is used as a term meaning that a joint of the lower sheet 10 with the wick sheet 30 can be maintained and a joint of the upper sheet 20 with the wick sheet 30 can be maintained to such an extent that the sealability of the sealed space 3 can be maintained during operation of the vapor chamber 1.

As shown in FIGS. 3 to 5, the wick sheet 30 according to the present embodiment has a frame 32 and lands 33. The frame 32 is formed in a rectangular frame shape in a plan view. The lands 33 are provided in the frame 32. The frame 32 and the lands 33 are portions where the material of the wick sheet 30 is left without being removed by etching in an etching process (described later). In the present embodiment, the frame 32 is formed in a rectangular frame shape in a plan view. The configuration is not limited thereto. The frame 32 may have a selected shape, such as a circular frame shape, an elliptical frame shape, an L-frame shape, a T-frame shape, and a U-frame shape. The vapor channel 50 is defined inside the frame 32. In other words, the working vapor 2a flows inside the frame 32 and around the lands 33.

In the present embodiment, the wick sheet 30 is provided with the plurality of lands 33, and the plurality of lands 33 extends in a fan shape from the heat source region SR toward the condensation region CR. In other words, the plurality of lands 33 extends radially outward in a plane direction from the heat source region SR side. The planar shape of each land 33 is a long slender rectangular shape. The configuration is not limited thereto. The planar shape of each land 33 may be a selected shape, including a polygonal shape, such as a trapezoidal shape and a triangular shape, and a shape surrounded by a curve, such as a circular arc. Each land 33 is disposed so as to be spaced apart from another one of the lands 33 via a vapor passage 51 (described later). A working vapor 2a is configured to flow around the lands 33 so as to be transferred toward the condensation region CR. Thus, interference with the flow of working vapor 2a is suppressed.

In the specification, a state where members A “radially” extend means that center lines in a width direction of two or more members A adjacent to each other separate from each other from one side toward the other side in extension directions of the members A. In the present embodiment, in all the region in the longitudinal direction of the two lands 33 adjacent to each other, the center lines in the width direction may separate from each other from one side toward the other side in the extension directions of the lands 33. Alternatively, in a part in the extension directions of the two lands 33 adjacent to each other, the center lines in the width direction may separate from each other from one side toward the other side in the extension directions of the lands 33. Alternatively, the center lines in the width direction of the three or more lands 33 may separate from each other from one side toward the other side in the extension directions of the lands 33. Alternatively, the center lines in the width direction of all the lands 33 included in the wick sheet 30 may separate from each other from one side toward the other side in the extension directions of the lands 33. The center lines in the width direction of the plurality of lands 33 extending radially may intersect at a single point or do not need to intersect at a single point. The plurality of lands 33 may radially extend over all the region in the circumferential direction with respect to a predetermined center position or may radially extend in part of the region in the circumferential direction. The predetermined center position may be in the heat source region SR or may be outside the heat source region SR.

When the predetermined center position is outside the heat source region SR as shown in FIG. 2, the area of the liquid channels 60 that overlap the heat source region SR can be increased. For this reason, a large amount of working liquid 2b can be stored in the heat source region SR, with the result that it is possible to suppress shortage of the working liquid 2b when the temperature of the device D rapidly increases. When the lengths of the lands 33 in the extension directions are different from each other, the liquid channels 60 with a long transfer distance for the working liquid 2b are allowed to overlap the heat source region SR in a wide range. Thus, it is possible to efficiently transfer the working vapor 2a in the vapor chamber 1 and efficiently return the condensed working liquid 2b to the heat source side.

The width w1 (see FIGS. 3 and 5) of each land 33 is not uniform in the extension direction of the land 33 and gradually widens from one side toward the other side in the extension direction of the land 33. In other words, the width w1 of each land 33 gradually widens with distance from the heat source region SR. Here, the width w1 of each land 33 corresponds to the length of a line segment connecting the intersections of a circle inscribed in the land 33 in a plan view with both side walls of the land 33 (see FIG. 5). The width w1 of each land 33 means a dimension at the largest position (for example, a position where a protrusion 55 is present) in a thickness direction (Z direction) of the land 33. The width w1 of each land 33 at the widest portion (for example, a portion farthest from the heat source region SR) in the extension direction may be, for example, greater than or equal to 30 μm and less than or equal to 3000 μm. Of the plurality of lands 33, the width w1 of each of some of the lands 33 may gradually widen from one side toward the other side in the extension direction of the land 33, and the width w1 of each of the other some of the lands 33 may be uniform in the extension direction of the land 33.

The frame 32 and the lands 33 are diffusion-joined to the lower sheet 10 and diffusion-joined to the upper sheet 20. Thus, the mechanical strength of the vapor chamber 1 is improved. First wall surfaces 53a and second wall surfaces 54a of the vapor passages 51 (described later) are components of side walls of the lands 33. The first main body surface 31a and the second main body surface 31b of the wick sheet 30 may be formed in a flat shape over the frame 32 and the lands 33.

The vapor channel 50 is mainly a channel through which vapor of a working fluid (referred to as working vapor 2a as needed) passes. The vapor channel 50 extends from the first main body surface 31a to the second main body surface 31b. The vapor channel 50 extends through the wick sheet 30.

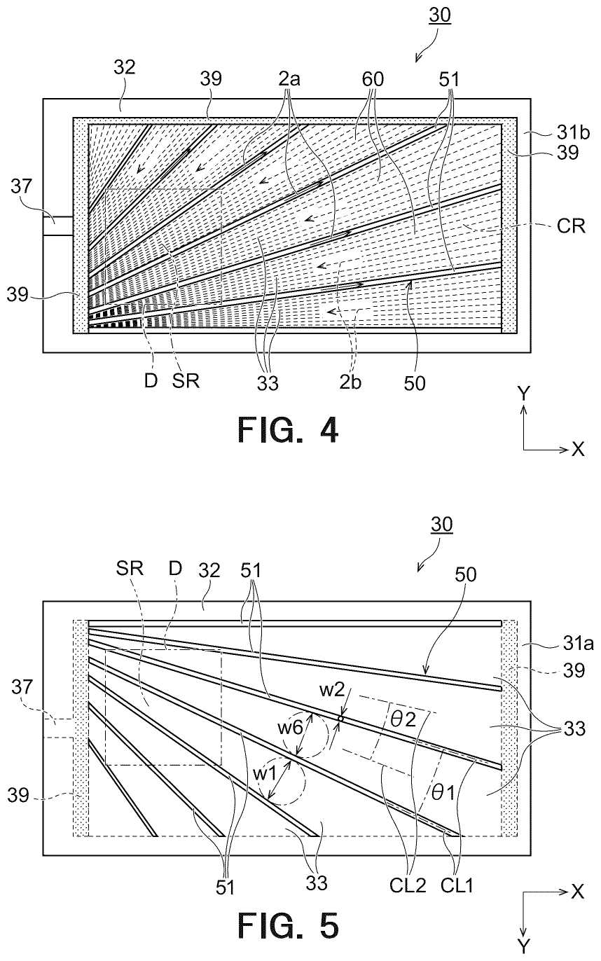

As shown in FIGS. 4 and 5, the vapor channel 50 has the plurality of vapor passages 51. The plurality of vapor passages 51 radially extend from part of the region (heat source region SR) toward the outer side (condensation region CR). In other words, the plurality of vapor passages 51 extends radially outward in a plane direction from the heat source region SR side. The vapor passages 51 are formed inside the frame 32 and outside the lands 33, that is, between the frame 32 and the lands 33 and between any adjacent two of the lands 33. The planar shape of each vapor passage 51 is a long slender rectangular shape. The configuration is not limited thereto. The planar shape of each vapor passage 51 may be a selected shape, such as a curved shape, including a circular arc and an S-shape, and a bent line shape, including a V-shape and an L-shape. The vapor channel 50 is partitioned into the plurality of vapor passages 51 by the plurality of lands 33. Center lines CL1 in the width direction of two vapor passages 51 adjacent to each other are not parallel to each other. An angle θ1 formed between the center lines CL1 in the width direction of the vapor passages 51 adjacent to each other may be larger than or equal to 0.5° and smaller than or equal to 10°. Each vapor passage 51 may be disposed so as to be spaced apart from another one of the vapor passages 51 via the land 33. The width w2 (see FIGS. 3 and 5) of each vapor passage 51 is uniform in the extension direction of the land 33.

In the present embodiment, in a part in the extension directions of the two vapor passages 51 adjacent to each other, the center lines in the width direction may separate from each other from one side toward the other side in the extension directions. Alternatively, the center lines in the width direction of the three or more vapor passages 51 may separate from each other from one side toward the other side in the extension directions of the vapor passages 51. Alternatively, the center lines in the width direction of all the vapor passages 51 included in the wick sheet 30 may separate from each other from one side toward the other side in the extension directions of the vapor passages 51. The center lines in the width direction of the plurality of vapor passages 51 extending radially may intersect at a single point or do not need to intersect at a single point. The plurality of vapor passages 51 may radially extend over all the region in the circumferential direction with respect to a predetermined center position or may radially extend in part of the region in the circumferential direction. The predetermined center position may be in the heat source region SR or may be outside the heat source region SR.

As shown in FIG. 3, the vapor passages 51 are formed so as to extend from the first main body surface 31a to the second main body surface 31b of the wick sheet 30. The vapor passages 51 are formed so as to extend through the wick sheet 30 from the first main body surface 31a to the second main body surface 31b of the wick sheet 30.

The vapor passages 51 may be formed by etching from each of the first main body surface 31a and the second main body surface 31b of the wick sheet 30 in the etching process (described later). In this case, as shown in FIG. 3, each of the vapor passages 51 has the first wall surfaces 53a formed in a curved shape and the second wall surfaces 54a formed in a curved shape. The first wall surface 53a is located adjacent to the first main body surface 31a. The first wall surface 53a is curved in a shape recessed inward of the land 33 in the width direction. The second wall surface 54a is located adjacent to the second main body surface 31b. The second wall surface 54a is curved in a shape recessed inward of the land 33 in the width direction. The first wall surface 53a and the second wall surface 54a meet at the protrusion 55 formed so as to project inward of the vapor passage 51. The protrusion 55 may be formed in an acute angle shape in a sectional view. A plane area of the vapor passage 51 is minimum at a position where the protrusion 55 is present. The width w2 (see FIGS. 3 and 5) of the vapor passage 51 may be, for example, greater than or equal to 100 μm and less than or equal to 5000 μm. Here, the width w2 of the vapor passage 51 corresponds to the length of a line segment connecting the intersections of a circle inscribed in the vapor passage 51 in a plan view with both side edges of the vapor passage 51 (see FIG. 5). The width w2 of the vapor passage 51 is a width at the narrowest part of the vapor passage 51 in the thickness direction (Z direction) and, in this case, means a distance measured at a position where the protrusions 55 are present. The width w2 of the vapor passage 51 also corresponds to a gap between the adjacent lands 33 in the width direction. In the thickness direction of the vapor passage 51, the width of the vapor passage 51 at the first main body surface 31a is defined as w2A, and the width of the vapor passage 51 at the second main body surface 31b is defined as w2B. At this time, the width w2A and the width w2B may be different from each other or may be equal to each other.

The position of the protrusion 55 in the thickness direction (Z direction) of the wick sheet 30 is shifted toward the second main body surface 31b with respect to a middle position between the first main body surface 31a and the second main body surface 31b. Where the distance between the protrusion 55 and the second main body surface 31b is t5 (see FIG. 3), the distance t5 may be greater than or equal to 5% of the thickness t4 (see FIG. 3) of the wick sheet 30 (described later), or may be greater than or equal to 10% of the thickness t4, or may be greater than or equal to 20% of the thickness t4. The distance t5 may be less than or equal to 50% of the thickness t4 of the wick sheet 30, may be less than or equal to 40% of the thickness t4, or may be less than or equal to 30% of the thickness t4. The configuration is not limited thereto. The position of the protrusion 55 in the thickness direction (Z direction) of the wick sheet 30 may be the center position between the first main body surface 31a and the second main body surface 31b. The position of the protrusion 55 in the thickness direction (Z direction) of the wick sheet 30 may be a position shifted toward the first main body surface 31a with respect to the center position. When the vapor passage 51 extends through in the thickness direction (Z direction) of the wick sheet 30, the position of the protrusion 55 is selectable.

In the present embodiment, the sectional shape of the vapor passage 51 is defined by the protrusion 55 formed so as to project inward of the vapor passage 51; however, the configuration is not limited thereto. For example, the sectional shape of the vapor passage 51 may be a trapezoidal shape or a rectangular shape or may be a barrel shape.

The vapor channel 50 including the vapor passages 51 configured in this way is part of the above-described sealed space 3. As shown in FIG. 3, the vapor channel 50 according to the present embodiment is mainly defined by the lower sheet 10, the upper sheet 20, and the frame 32 and lands 33 of the above-described wick sheet 30. Each of the vapor passages 51 has a relatively large channel cross-sectional area such that the working vapor 2a passes.

As shown in FIGS. 4 and 5, a supporting portion 39 that supports the lands 33 on the frame 32 is provided in the vapor channel 50. The supporting portion 39 supports any adjacent two of the lands 33. The supporting portion 39 is provided on one side of the lands 33 in the longitudinal direction. The supporting portion 39 may be provided on each side of the lands 33 in the longitudinal direction. The supporting portion 39 is preferably formed so as not to impede flow of the working vapor 2a that diffuses in the vapor channel 50. In this case, the supporting portion 39 is disposed adjacent to the first main body surface 31a of the wick sheet 30, and a space that communicates with the vapor channel 50 is formed adjacent to the second main body surface 31b. In other words, in FIGS. 4 and 5, the supporting portion 39 is shaded. The supporting portion 39 is thinned by half-etching from the second main body surface 31b side. The supporting portion 39 is a region that does not extend through the wick sheet 30 in the thickness direction and is thinner in thickness than the frame 32. As a result, the thickness of the supporting portion 39 can be made less than the thickness of the wick sheet 30, so it is possible to suppress separation of each of the vapor passages 51 in the X direction or in the Y direction. However, the configuration is not limited thereto. The supporting portion 39 may be disposed adjacent to the second main body surface 31b. A space that communicates with the vapor channel 50 may be formed on each of the first main body surface 31a-side surface and the second main body surface 31b-side surface of the supporting portion 39.

As shown in FIG. 2, the vapor chamber 1 may further include a filling portion 4 at one-side (negative-side in the X direction) edge in the X direction. The filling portion 4 is used to fill the working liquid 2b into the sealed space 3. In the mode shown in FIG. 2, the filling portion 4 is disposed adjacent to the heat source region SR. The filling portion 4 has a filling channel 37 formed in the wick sheet 30. The filling channel 37 is formed adjacent the second main body surface 31b of the wick sheet 30 and is formed into a recess shape from the second main body surface 31b side. After the vapor chamber 1 is complete, the filling channel 37 is sealed. The filling channel 37 communicates with the vapor channel 50, and the working liquid 2b is filled into the sealed space 3 through the filling channel 37. Depending on the arrangement of the liquid channels 60, the filling channel 37 may communicate with the liquid channels 60.

In the present embodiment, an example in which the filling portion 4 is provided at one-side edge of a pair of edges of the vapor chamber 1 in the X direction is described. The configuration is not limited thereto. The filling portion 4 may be provided at a selected position.

As shown in FIGS. 3 and 4, the liquid channels 60 are provided on the second main body surface 31b (heat receiving surface side) of the wick sheet 30. The liquid channels 60 may be provided on the first main body surface 31a (heat dissipation surface side). The liquid channels 60 are mainly channels through which the working liquid 2b passes. The liquid channels 60 are part of the above-described sealed space 3 and communicate with the vapor channel 50. Each of the liquid channels 60 is configured as a capillary structure (wick) for transferring the working liquid 2b to the heat source region SR. In the present embodiment, the liquid channel 60 is provided on the second main body surface 31b of each of the lands 33 of the wick sheet 30. The liquid channel 60 may be formed over the entire second main body surface 31b of each land 33. Of the plurality of lands 33, the liquid channel 60 does not need to be formed in one or some of the lands 33.

In the present embodiment, each of the plurality of lands 33 is provided with the liquid channel 60, and the plurality of liquid channels 60 radially extends from part of the region (heat source region SR) toward the outer side (condensation region CR). In other words, the plurality of liquid channels 60 extends radially outward in a plane direction from the heat source region SR side. As shown in FIG. 5, center lines CL2 in the width direction of two liquid channels 60 adjacent to each other are not parallel to each other. An angle θ2 formed between the center lines CL2 in the width direction of the two liquid channels 60 adjacent to each other may be larger than or equal to 0.5° and smaller than or equal to 10°.

The width w6 (see FIG. 3) of each liquid channel 60 is not uniform in the extension direction of the liquid channel 60 and gradually widens from one side toward the other side in the extension direction of the liquid channel 60. In other words, the width w6 of each liquid channel 60 gradually widens with distance from the heat source region SR. Here, the width w6 of the liquid channel 60 corresponds to the length of a line segment connecting the intersections of a circle inscribed in the liquid channel 60 in a plan view with both side edges of the liquid channel 60 (see FIG. 5). The width w6 of the liquid channel 60 means a dimension at the second main body surface 31b. The width w6 of each liquid channel 60 at the widest portion (for example, a portion farthest from the heat source region SR) in the extension direction of the liquid channel 60 may be, for example, greater than or equal to 30 μm and less than or equal to 3000 μm. When measured at the same position in a plan view, the width w6 of the liquid channel 60 may be equal to the width w1 of the above-described land 33 or may be narrower than the width w1 of the land 33. Of the plurality of liquid channels 60, the width w6 of each of some of the liquid channels 60 may gradually widen from one side toward the other side in the extension direction of the liquid channel 60, and the width w6 of each of the other some of the liquid channels 60 may be uniform in the extension direction of the liquid channel 60.

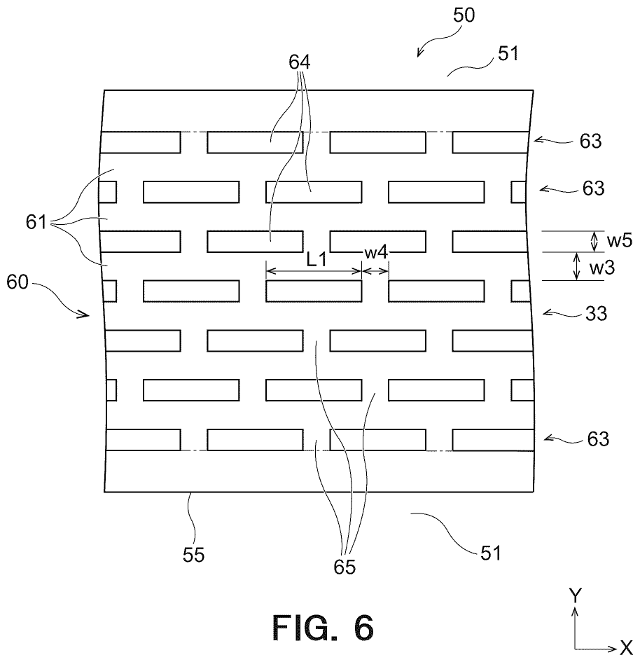

As shown in FIG. 6, the liquid channel 60 has a plurality of liquid channel main stream grooves 61 and a plurality of liquid channel communication grooves 65. The plurality of liquid channel main stream grooves 61 is the one through which the working liquid 2b passes and disposed so as to run side by side to each other. The plurality of liquid channel communication grooves 65 communicates with the liquid channel main stream grooves 61. In the example shown in FIG. 6, each land 33 includes six liquid channel main stream grooves 61; however, the configuration is not limited thereto. The number of the liquid channel main stream grooves 61 included in each land 33 is selectable and may be, for example, greater than or equal to three and less than or equal to 20. As described above, the width w6 of each liquid channel 60 gradually widens from one side toward the other side in the extension direction of the liquid channel 60. For this reason, the number of the liquid channel main stream grooves 61 included in each land 33 may be changed in the extension direction of the liquid channel 60. For example, the number of the liquid channel main stream grooves 61 may increase from one side toward the other side in the extension direction, that is, as the width w6 of the liquid channel 60 widens.

As shown in FIG. 6, each liquid channel main stream groove 61 is formed so as to extend in the longitudinal direction of the land 33. The plurality of liquid channel main stream grooves 61 may be disposed so as to be parallel to one another or may be disposed so as not to be parallel to one another. As described above, the width w6 of each liquid channel 60 gradually widens from one side toward the other side in the extension direction of the liquid channel 60. For this reason, the plurality of liquid channel main stream grooves 61 may radially extend from the heat source region SR side toward the condensation region CR side in accordance with the shape of each liquid channel 60. When the land 33 is curved in a plan view, each liquid channel main stream groove 61 may extend in a curved shape in a curved direction of the land 33. In other words, each liquid channel main stream groove 61 may be formed not always in a straight line shape.

The liquid channel main stream groove 61 has a channel cross-sectional area smaller than that of the vapor passage 51 of the vapor channel 50 such that the working liquid 2b mainly flows by capillary action. The liquid channel main stream grooves 61 are configured to transfer the working liquid 2b, condensed from the working vapor 2a, to the heat source region SR. The liquid channel main stream grooves 61 are disposed so as to be spaced at intervals in the width direction of the land 33.

The liquid channel main stream grooves 61 are formed by etching from the second main body surface 31b of the wick sheet 30 in the etching process (described later). Each liquid channel main stream groove 61 has a wall surface 62 formed in a curved shape as shown in FIG. 3. The wall surface 62 defines the liquid channel main stream groove 61 and is curved so as to be recessed from the second main body surface 31b side toward the first main body surface 31a side. In the cross section shown in FIG. 3, the radius of curvature of each wall surface 62 is preferably less than the radius of curvature of the second wall surface 54a of the vapor passage 51.

In FIG. 6, the width w3 of the liquid channel main stream groove 61 may be, for example, greater than or equal to 2 μm and less than or equal to 500 μm. The width w3 of the liquid channel main stream groove 61 is the length in a direction perpendicular to the longitudinal direction of the land 33. The width w3 of the liquid channel main stream groove 61 means a dimension at the second main body surface 31b. When the width w3 of the liquid channel main stream groove 61 is changed in the longitudinal direction of the land 33, the width w3 of the liquid channel main stream groove 61 means a value measured at the widest portion. As described above, the width w6 of each liquid channel 60 gradually widens from one side toward the other side in the extension direction of the liquid channel 60. For this reason, the width w3 of each liquid channel main stream groove 61 may be changed in the extension direction of the liquid channel 60. For example, the width w3 of the liquid channel main stream groove 61 may widen from one side toward the other side in the extension direction of the liquid channel 60.

As shown in FIG. 3, the depth h1 of the liquid channel main stream groove 61 may be, for example, greater than or equal to 3 μm and less than or equal to 300 μm. The depth h1 of the liquid channel main stream groove 61 is a distance measured in a direction perpendicular to the second main body surface 31b from the second main body surface 31b and, in this case, is a dimension in the Z direction. The depth h1 means a depth at the deepest point of the liquid channel main stream groove 61.

As shown in FIG. 6, each liquid channel communication groove 65 extends in a direction different from the extension direction of the liquid channel main stream groove 61. In the present embodiment, each liquid channel communication groove 65 is formed perpendicularly to the extension direction of the liquid channel main stream groove 61. Some of the liquid channel communication grooves 65 each are disposed so as to communicate adjacent two of the liquid channel main stream grooves 61. The other liquid channel communication grooves 65 each are disposed so as to communicate the vapor channel 50 (vapor passage 51) with the liquid channel main stream groove 61 closest to the vapor channel 50. In other words, the liquid channel communication groove 65 extends from an end side of the land 33 in the width direction to the liquid channel main stream groove 61 adjacent to the end. In this way, the vapor passage 51 of the vapor channel 50 communicates with the liquid channel main stream groove 61.

The liquid channel communication groove 65 has a channel cross-sectional area smaller than that of the vapor passage 51 of the vapor channel 50 such that the working liquid 2b mainly flows by capillary action. The liquid channel communication grooves 65 may be disposed so as to be spaced at equal intervals in the longitudinal direction of the land 33.

Each of the liquid channel communication grooves 65, as well as the liquid channel main stream grooves 61, is formed by etching and has a wall surface (not shown) formed in a curved shape similar to that of the liquid channel main stream groove 61. As shown in FIG. 6, the width w4 of the liquid channel communication groove 65 (a dimension in the longitudinal direction of the land 33) may be greater than or equal to 5 μm and less than or equal to 300 μm. The depth of the liquid channel communication groove 65 may be greater than or equal to 3 μm and less than or equal to 300 μm.

As shown in FIG. 6, a protrusion array 63 is provided between adjacent two of the liquid channel main stream grooves 61 of the liquid channel 60. In the example shown in FIG. 6, an example in which each land 33 includes seven protrusion arrays 63 is described; however, the configuration is not limited thereto. The number of the protrusion arrays 63 included in each land 33 is selectable and may be, for example, greater than or equal to three and less than or equal to 20. As described above, the width w6 of each liquid channel 60 gradually widens from one side toward the other side in the extension direction of the liquid channel 60. For this reason, the number of the protrusion arrays 63 included in each land 33 may be changed in the extension direction of the liquid channel 60. For example, the number of the protrusion arrays 63 may increase from one side toward the other side in the extension direction of the liquid channel 60, that is, as the width w6 of the liquid channel 60 widens.

As shown in FIG. 6, each protrusion array 63 is formed so as to extend in the longitudinal direction of the land 33. The plurality of protrusion arrays 63 may be disposed so as to be parallel to one another or may be disposed so as not to be parallel to one another. When the land 33 is curved in a plan view, each protrusion array 63 may extend in a curved shape in a curved direction of the land 33. In other words, each protrusion array 63 may be formed not always in a straight line shape. Each protrusion array 63 is disposed so as to be spaced at intervals in the width direction of the land 33.

Each protrusion array 63 includes a plurality of protrusions 64 (liquid channel protrusions) arranged in the longitudinal direction of the land 33. The protrusions 64 are provided in the liquid channel 60. The protrusions 64 protrude from the liquid channel main stream grooves 61 and the liquid channel communication grooves 65 and contact with the upper sheet 20. The liquid channel main stream groove 61 is disposed between any adjacent two of the protrusions 64 in the width direction of the land 33. The liquid channel communication groove 65 is disposed between any adjacent two of the protrusions 64 in the longitudinal direction of the land 33. The liquid channel communication groove 65 is formed so as to extend in the width direction of the land 33 and communicates adjacent two of the liquid channel main stream grooves 61 in the width direction. As a result, the working liquid 2b is allowed to move among these liquid channel main stream grooves 61.

The protrusions 64 are portions where the material of the wick sheet 30 is left without being removed by etching in the etching process (described later). In the present embodiment, as shown in FIG. 6, the planar shape of each protrusion 64 (the shape at the position of the second main body surface 31b of the wick sheet 30) is a rectangular shape. However, the configuration is not limited thereto. The protrusion 64 may be not always a rectangular shape in a plan view. For example, the protrusion 64 may have a shape of which the width widens from one side (heat source region SR side) toward the other side (condensation region CR side) in a plan view, for example, a trapezoidal shape. The width w5 of the protrusion 64 at the widest position may be, for example, greater than or equal to 5 μm and less than or equal to 500 μm.

In the present embodiment, the protrusions 64 are disposed in a staggered manner (alternately). More specifically, the protrusions 64 of the adjacent two of the protrusion arrays 63 in the width direction of the land 33 are disposed so as to be shifted from each other in the longitudinal direction of the land 33. The shift amount may be half the array pitch of the protrusions 64 in the longitudinal direction of the land 33. The arrangement of the protrusions 64 is not limited to the staggered manner and may be a parallel array. In this case, the protrusions 64 of adjacent two of the protrusion arrays 63 in the width direction of the land 33 are aligned also in the longitudinal direction of the land 33.

The length L1 (a dimension in the longitudinal direction of the land 33) of the protrusion 64 may be uniform among the protrusions 64. The length L1 of the protrusion 64 is greater than the width w4 of the liquid channel communication groove 65 (L1>w4). The length L1 of the protrusion 64 means a maximum dimension at the second main body surface 31b.

Incidentally, the material of the lower sheet 10, the upper sheet 20, and the wick sheet 30 is not limited as long as the material has a good thermal conductivity. The lower sheet 10, the upper sheet 20, and the wick sheet 30 may contain, for example, copper or a copper alloy. In this case, it is possible to enhance the thermal conductivity of each of the sheets 10, 20, 30, and it is possible to enhance the heat dissipation efficiency of the vapor chamber 1. When pure water is used as the working fluids 2a, 2b, it is possible to suppress corrosion. If it is possible to obtain a desired heat dissipation efficiency and suppress corrosion, another metal material, such as aluminum and titanium, or another metal alloy material, such as stainless steel, may be used for these sheets 10, 20, 30.

The thickness t1 of the vapor chamber 1 shown in FIG. 3 may be, for example, greater than or equal to 100 μm and less than or equal to 2000 μm. When the thickness t1 is greater than or equal to 100 μm, it is possible to cause the vapor chamber 1 to appropriately function by appropriately ensuring the vapor channel 50. On the other hand, when the thickness t1 is less than or equal to 2000 μm, it is possible to suppress an increase in the thickness t1 of the vapor chamber 1.

The thickness t2 of the lower sheet 10 may be, for example, greater than or equal to 5 μm and less than or equal to 500 μm. When the thickness t2 is greater than or equal to 5 μm, it is possible to ensure the mechanical strength of the lower sheet 10. On the other hand, when the thickness t2 is less than or equal to 500 μm, it is possible to suppress an increase in the thickness t1 of the vapor chamber 1. Similarly, the thickness t3 of the upper sheet 20 may be set as in the case of the thickness t2 of the lower sheet 10. The thickness t3 of the upper sheet 20 and the thickness t2 of the lower sheet 10 may be different from each other.

The thickness t4 of the wick sheet 30 may be, for example, greater than or equal to 50 μm and less than or equal to 1000 μm. When the thickness t4 is greater than or equal to 50 μm, it is possible to cause the vapor chamber 1 to appropriately function by appropriately ensuring the vapor channel 50. On the other hand, when the thickness t4 is less than or equal to 1000 μm, it is possible to suppress an increase in the thickness t1 of the vapor chamber 1.

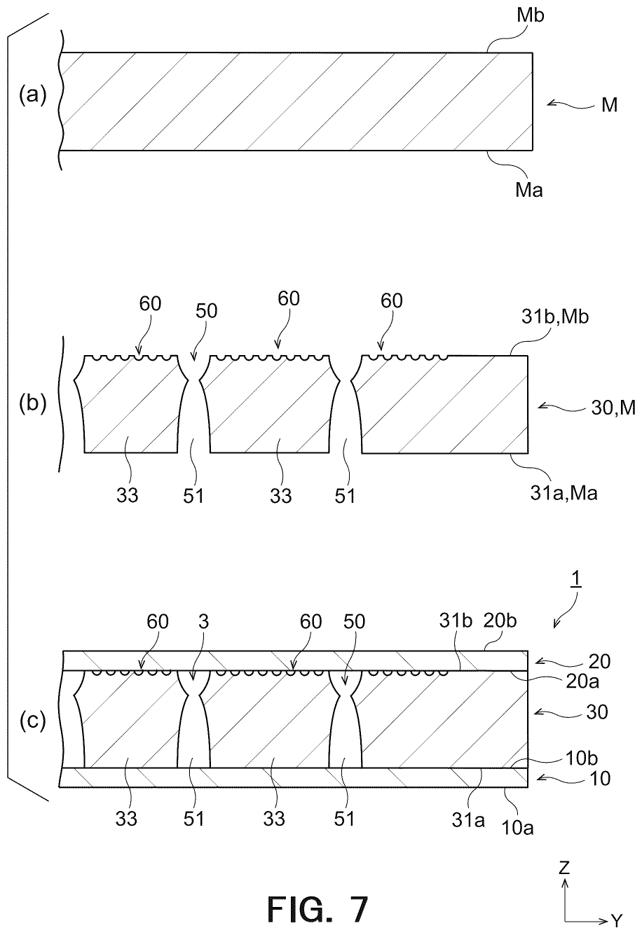

Next, a manufacturing method for the thus configured vapor chamber 1 according to the present embodiment will be described with reference to FIGS. 7(a) to 7(c). FIGS. 7(a) to 7(c) show substantially similar sectional views to the sectional view of FIG. 3.

Here, initially, a manufacturing process for the wick sheet 30 will be described.

Initially, as shown in FIG. 7(a), in a preparation process, a sheet-shaped metal material sheet M is prepared. The metal material sheet M includes a first material surface Ma and a second material surface Mb.

After the preparation process, as the etching process, as shown in FIG. 7(b), the metal material sheet M is etched from the first material surface Ma and the second material surface Mb to form the vapor channel 50 and the liquid channels 60.

More specifically, a patterned resist film (not shown) is formed on the first material surface Ma and the second material surface Mb of the metal material sheet M by a photolithography technology. Subsequently, the first material surface Ma and the second material surface Mb of the metal material sheet M are etched through the openings of the patterned resist film. Thus, the first material surface Ma and the second material surface Mb of the metal material sheet M are etched into a patterned shape to form the vapor channel 50 and the liquid channels 60 as shown in FIG. 7(b). For example, a ferric chloride etchant, such as aqueous ferric chloride, or a copper chloride etchant, such as aqueous copper chloride, may be used as an etchant.

The first material surface Ma and the second material surface Mb of the metal material sheet M may be etched at the same time. However, not limited to this configuration, etching of the first material surface Ma and etching of the second material surface Mb may be performed in different processes. The vapor channel 50 and the liquid channels 60 may be formed by etching at the same time or may be formed in different processes. In the etching process, a predetermined outline shape as shown in FIGS. 4 and 5 can be obtained by etching the first material surface Ma and the second material surface Mb of the metal material sheet M. In other words, the end edge of the wick sheet 30 is formed.

In this way, the wick sheet 30 according to the present embodiment is obtained.

After the manufacturing process of the wick sheet 30, the lower sheet 10, the upper sheet 20, and the wick sheet 30 are joined together as shown in FIG. 7(c) in a joining process. The lower sheet 10 and the upper sheet 20 may be formed from a rolled material having a desired thickness.

More specifically, initially, the lower sheet 10, the wick sheet 30, and the upper sheet 20 are laminated in this order. In this case, the first main body surface 31a of the wick sheet 30 is superimposed on the second lower sheet surface 10b of the lower sheet 10. The first upper sheet surface 20a of the upper sheet 20 is superimposed on the second main body surface 31b of the wick sheet 30.

Subsequently, the lower sheet 10, the wick sheet 30, and the upper sheet 20 are temporarily joined. For example, these sheets 10, 20, 30 may be temporarily joined by spot resistance welding. These sheets 10, 20, 30 may be temporarily joined by laser welding.

After that, the lower sheet 10, the wick sheet 30, and the upper sheet 20 are permanently joined by diffusion joining. Diffusion joining is a joining method as follows. In other words, initially, the lower sheet 10 and the wick sheet 30 to be joined are brought into close contact with each other, and the wick sheet 30 and the upper sheet 20 are brought into close contact with each other. Subsequently, the lower sheet 10, the wick sheet 30, and the upper sheet 20 are joined by means of diffusion of atoms that occurs on a joint surface by pressurizing and heating in a laminated direction in a controlled atmosphere, such as vacuum and inert gas. Diffusion joining heats the materials of the sheets 10, 20, 30 to a temperature close to a melting point but lower than the melting point, so it is possible to avoid melting and deformation of each of the sheets 10, 20, 30. More specifically, the first main body surface 31a at each of the frame 32 and the lands 33 of the wick sheet 30 is diffusion-joined with the second lower sheet surface 10b of the lower sheet 10. The second main body surface 31b at each of the frame 32 and the lands 33 of the wick sheet 30 is diffusion-joined with the first upper sheet surface 20a of the upper sheet 20 surface. In this way, the sheets 10, 20, 30 are diffusion-joined, and the sealed space 3 having the vapor channel 50 and the liquid channel 60 is formed between the lower sheet 10 and the upper sheet 20.

After the joining process, the working liquid 2b is filled into the sealed space 3 through the filling portion 4.

After that, the above-described filling channel 37 is sealed. For example, the filling channel 37 may be sealed by partially melting the filling portion 4. Thus, communication between the sealed space 3 and the outside is interrupted, and the working liquid 2b is filled into the sealed space 3, so leakage of the working liquid 2b in the sealed space 3 to the outside is suppressed.

In this way, the vapor chamber 1 according to the present embodiment is obtained.

Next, an operation method for the vapor chamber 1, that is, a method of cooling the device D, will be described.

The vapor chamber 1 obtained as described above is installed in the housing H of the electronic apparatus E, such as a mobile terminal. The device D, such as a CPU, that is, a device to be cooled, is attached to the second upper sheet surface 20b of the upper sheet 20 (or the vapor chamber 1 is attached to the device D). The working liquid 2b in the sealed space 3 adheres, with its surface tension, to the wall surface of the sealed space 3, that is, the first wall surfaces 53a and the second wall surfaces 54a of the vapor passages 51, and the wall surfaces 62 of the liquid channel main stream grooves 61 and the wall surfaces of the liquid channel communication grooves 65 of the liquid channels 60. The working liquid 2b can also adhere to portions exposed to the vapor passages 51, of the second lower sheet surface 10b of the lower sheet 10. Furthermore, the working liquid 2b can also adhere to portions exposed to the vapor passages 51, the liquid channel main stream grooves 61, and the liquid channel communication grooves 65, of the first upper sheet surface 20a of the upper sheet 20.

When the device D generates heat in this state, the working liquid 2b present in the heat source region SR (see FIGS. 4 and 5) receives heat from the device D. The working liquid 2b absorbs the received heat as latent heat to be vaporized (evaporated) into the working vapor 2a. Most of the produced working vapor 2a diffuses in the vapor passages 51 that are components of the sealed space 3 (see the continuous line arrows in FIG. 4). The working vapor 2a in each vapor passage 51 leaves from the heat source region SR, and most of the working vapor 2a is transferred to the condensation region CR with a relatively low temperature (a right-side part in FIGS. 4 and 5). In the condensation region CR, the working vapor 2a mainly dissipates heat to the lower sheet 10 to be cooled. Heat that the lower sheet 10 has received from the working vapor 2a is transferred to outside air via the housing member Ha (see FIG. 3).

The working vapor 2a dissipates heat to the lower sheet 10 in the condensation region CR and loses the latent heat absorbed in the heat source region SR to be condensed into the working liquid 2b. The produced working liquid 2b adheres to the first wall surfaces 53a and the second wall surfaces 54a of the vapor passages 51, the second lower sheet surface 10b of the lower sheet 10, and the first upper sheet surface 20a of the upper sheet 20. Here, the working liquid 2b continues to vaporize in the heat source region SR. Therefore, the working liquid 2b in a region other than the heat source region SR of the liquid channels 60 (that is, the condensation region CR) is transferred toward the heat source region SR by the capillary action of the liquid channel main stream grooves 61 (see the dashed line arrows in FIG. 4). Thus, the working liquid 2b having adhered to the vapor passages 51, the second lower sheet surface 10b, and the first upper sheet surface 20a moves to the liquid channels 60, passes through the liquid channel communication grooves 65, and enters the liquid channel main stream grooves 61. In this way, the liquid channel main stream grooves 61 and the liquid channel communication grooves 65 are filled with the working liquid 2b. Therefore, the filled working liquid 2b gains propelling force toward the heat source region SR by the capillary action of the liquid channel main stream grooves 61, and is transferred smoothly toward the heat source region SR.

In the liquid channels 60, each liquid channel main stream groove 61 communicates with another adjacent one of the liquid channel main stream grooves 61 via corresponding some of the liquid channel communication grooves 65. Thus, the working liquid 2b moves between the liquid channel main stream grooves 61 adjacent to each other. Therefore, the capillary action is imparted to the working liquid 2b in each liquid channel main stream groove 61, and the working liquid 2b is smoothly transferred toward the heat source region SR.

The working liquid 2b having reached the heat source region SR receives heat again from the device D to vaporize. The working vapor 2a vaporized from the working liquid 2b moves to the vapor passages 51 with a greater channel cross-sectional area through the liquid channel communication grooves 65 in the heat source region SR and diffuses in the vapor passages 51. In this way, the working fluids 2a, 2b circulate in the sealed space 3 while repeating a phase change, that is, vaporization and condensation, to transfer and dissipate heat of the device D. As a result, the device D is cooled.

Incidentally, in the present embodiment, the plurality of vapor passages 51 and the plurality of liquid channels 60 radially extend from part of the region (heat source region SR) toward the outer side (condensation region CR). Thus, it is possible to transfer the working vapor 2a in a direction toward a far and wide side from the device D that is a heat source and return the condensed working liquid 2b to the heat source side. Therefore, a region to which heat is difficult to be transferred is reduced in the plane of the vapor chamber 1, so it is possible to use a wide range of the vapor chamber 1 to transfer heat. Thus, it is possible to cause heat from the heat source to go around uniformly in the plane of the vapor chamber 1. As a result, the action that the working fluids 2a, 2b circulate in the sealed space 3 is facilitated, so it is possible to increase the heat dissipation efficiency of the vapor chamber 1.

According to the present embodiment, the width w6 of the liquid channel 60 gradually widens from one side toward the other side in the extension direction of the liquid channel 60. Thus, the working liquid 2b can be easily taken into the liquid channel 60 on the other side (condensation region CR side) in the extension direction of the liquid channel 60. As a result, the action that the working fluids 2a, 2b circulate in the sealed space 3 is facilitated, so it is possible to increase the heat dissipation efficiency of the vapor chamber 1. Since the area of the liquid channel 60 is widened on the other side (condensation region CR side) in the extension direction of the liquid channel 60, the working liquid 2b is less likely to stagnate at a specific portion of the liquid channel 60. Thus, when the vapor chamber 1 is placed in an environment lower in temperature than the freezing point of the working liquid 2b, it is possible to reduce freezing of the working liquid 2b remaining in the liquid channel 60 and, as a result, breakage of the vapor chamber 1. Resistance that the working vapor 2a flowing through the vapor passages 51 receives is uniform from the heat source region SR to the terminal end. Therefore, it is possible to smoothly flow the working vapor 2a. On the other hand, since the width of the liquid channel 60 increases from the heat source region SR toward the terminal end, it is possible to sufficiently recover the working liquid 2b frozen at the terminal end side, with the result that flow of the working vapor 2a and recovery of the working liquid 2b are achieved.

### Modifications

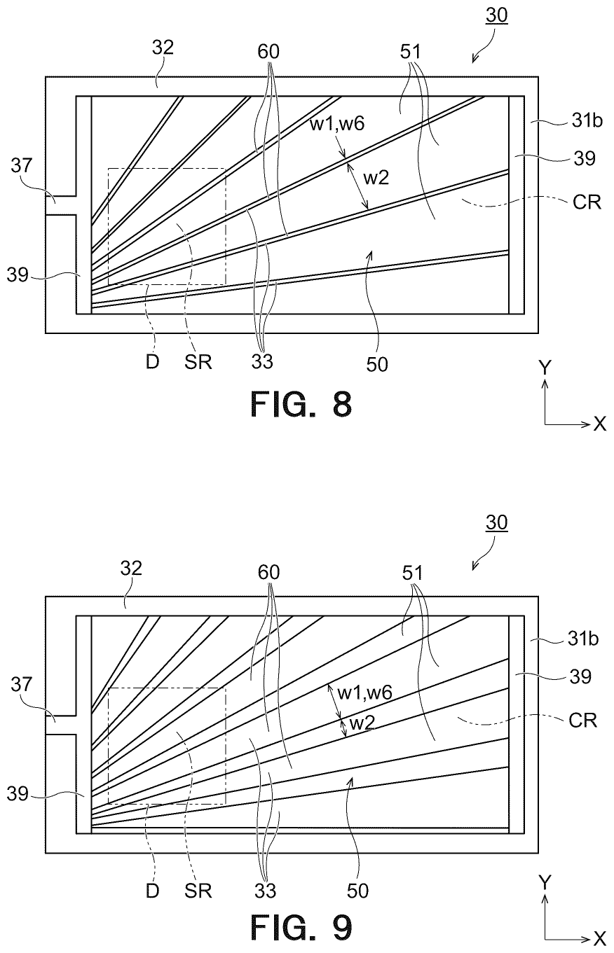

Next, various modifications of the present embodiment will be described with reference to FIGS. 8 to 25. FIGS. 8 to 25 are views respectively showing wick sheets 30 according to the modifications. In FIGS. 8 to 25, like reference signs are assigned to the same portions as those of the embodiment shown in FIGS. 1 to 7, and the detailed description is omitted.

### First Modification

As shown in FIG. 8, the plurality of vapor passages 51 and the plurality of liquid channels 60 radially extend from one side (heat source region SR) in the extension directions of the vapor passages 51 and the liquid channels 60. In FIG. 8, the width w2 of each vapor passage 51 is not uniform in the extension direction of the vapor passage 51 and gradually widens from one side toward the other side in the extension direction of the vapor passage 51. In other words, the width w2 of each vapor passage 51 gradually widens with distance from the heat source region SR. On the other hand, the width w1 of each land 33 and the width w6 of each liquid channel 60 are uniform in the extension direction of the land 33. In this case, the side face (the first wall surface 53a, the second wall surface 54a) of the vapor passage 51 is linear in a plan view. The configuration is not limited thereto. The side face (the first wall surface 53a, the second wall surface 54a) of the vapor passage 51 may be curved in a plan view. A value obtained by measuring the width w2 of each vapor passage 51 at the widest portion (for example, a portion farthest from the heat source region SR) in the extension direction of the vapor passage 51 may be, for example, greater than or equal to 30 μm and less than or equal to 3000 μm. Of the plurality of vapor passages 51, the width w2 of each of some of the vapor passages 51 may gradually widen from one side toward the other side in the extension direction of the vapor passage 51, and the width w2 of each of the other some of the vapor passages 51 may be uniform in the extension direction of the vapor passage 51.

According to the present modification, the width w2 of each vapor passage 51 gradually widens from one side toward the other side in the extension direction of the vapor passage 51. Therefore, when the working vapor 2a is transferred from one side (heat source region SR side) toward the other side (condensation region CR side) in the extension direction of the vapor passage 51, the pressure of the working vapor 2a can be gradually decreased. Thus, it is possible to reduce the vapor resistance of the working vapor 2a flowing through the vapor passages 51 and to easily transfer heat along the vapor passages 51. On the other hand, the width w1 of each land 33 and the width w6 of each liquid channel 60 each are equal from the heat source region SR to the terminal end. Thus, the working liquid 2b that returns from the terminal end to the heat source region SR flows at a constant rate without stagnation, so the working liquid 2b more easily flows. Efficient thermal uniformity is possible without excessive entry of the working liquid 2b.

In the present modification, the width w2A (see FIG. 3) of each vapor passage 51 at the first main body surface 31a may be not uniform in the extension direction of the vapor passage 51 and gradually widen from one side toward the other side in the extension direction of the vapor passage 51. Alternatively, the width w2B (see FIG. 3) of each vapor passage 51 at the second main body surface 31b may be not uniform in the extension direction of the vapor passage 51 and gradually widen from one side toward the other side in the extension direction of the vapor passage 51.

### Second Modification

As shown in FIG. 9, the plurality of vapor passages 51 and the plurality of liquid channels 60 radially extend from one side (heat source region SR) in the extension directions of the vapor passages 51 and the liquid channels 60. In FIG. 9, the width w2 of each vapor passage 51 is not uniform in the extension direction of the vapor passage 51 and gradually widens from one side toward the other side in the extension direction of the vapor passage 51. In other words, the width w2 of each vapor passage 51 gradually widens with distance from the heat source region SR. The width w1 of each land 33 and the width w6 of each liquid channel 60 each gradually widens from one side toward the other side in the extension directions of the land 33 and the liquid channel 60. In other words, the width w1 of each land 33 and the width w6 of each liquid channel 60 gradually widen with distance from the heat source region SR. A boundary surface (second wall surface 54a) between the vapor passage 51 and the liquid channel 60 is linear in a plan view; however, the configuration is not limited thereto. The boundary surface may be curved in a plan view.

Of the plurality of vapor passages 51, the width w2 of each of some of the vapor passages 51 may gradually widen from one side toward the other side in the extension direction of the vapor passage 51, and the width w2 of each of the other some of the vapor passages 51 may be uniform in the extension direction of the vapor passage 51. Of the plurality of liquid channels 60, the width w6 of each of some of the liquid channels 60 may gradually widen from one side toward the other side in the extension direction of the liquid channel 60, and the width w6 of each of the other some of the liquid channels 60 may be uniform in the extension direction of the liquid channel 60.

According to the present modification, the width w2 of each vapor passage 51 gradually widens with distance from the heat source region SR. Thus, it is possible to reduce the vapor resistance of the working vapor 2a flowing through the vapor passages 51 and to easily transfer heat along the vapor passages 51. Since the width w6 of each liquid channel 60 gradually widens with distance from the heat source region SR, the working liquid 2b can be easily taken into the liquid channel 60 on the condensation region CR side.

In the present modification, the width w2A (see FIG. 3) of each vapor passage 51 at the first main body surface 31a may be not uniform in the extension direction of the vapor passage 51 and gradually widen from one side toward the other side in the extension direction of the vapor passage 51. Alternatively, the width w2B (see FIG. 3) of each vapor passage 51 at the second main body surface 31b may be not uniform in the extension direction of the vapor passage 51 and gradually widen from one side toward the other side in the extension direction of the vapor passage 51.

### Third Modification

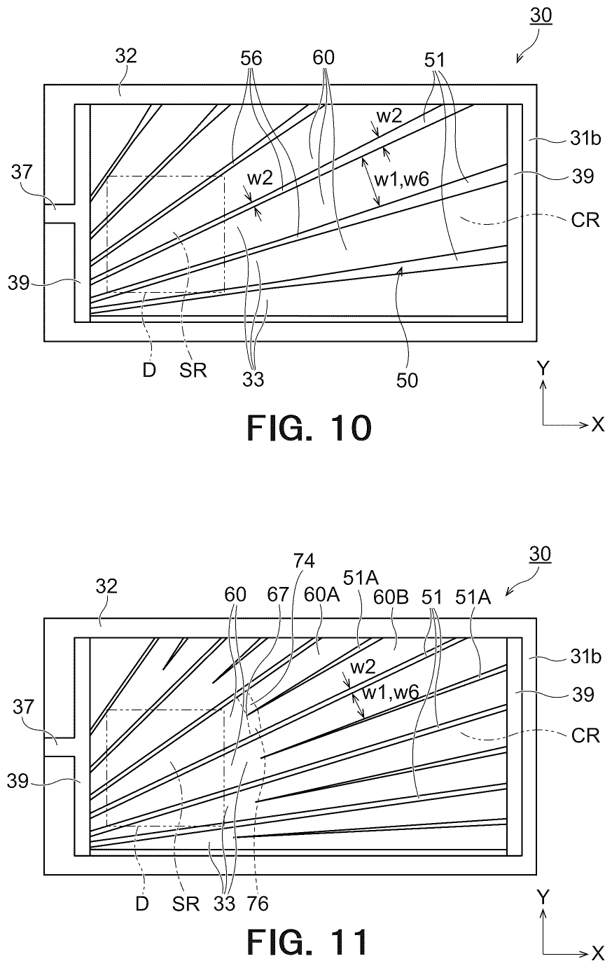

As shown in FIG. 10, the plurality of vapor passages 51 and the plurality of liquid channels 60 radially extend from one side (heat source region SR) in the extension directions of the vapor passages 51 and the liquid channels 60. In FIG. 10, the width change part 56 is located midway in the extension direction of the vapor passage 51. The width w2 of each vapor passage 51 is uniform from one side (heat source region SR side) to the width change part 56 in the extension direction of the vapor passage 51 and gradually widens from the width change part 56 toward the other side in the extension direction of the vapor passage 51. In other words, the width w2 of each vapor passage 51 is uniform on one side of the width change part 56 and gradually widens on the other side of the width change part 56 in the extension direction of the vapor passage 51. On the other hand, the width w1 of each land 33 and the width w6 of each liquid channel 60 gradually widen from one side toward the other side in the extension directions of the land 33 and the liquid channel 60. In other words, the width w1 of each land 33 and the width w6 of each liquid channel 60 gradually widen from the heat source region SR side to the condensation region CR side. A boundary surface (second wall surface 54a) between the vapor passage 51 and the liquid channel 60 is linear in a plan view; however, the configuration is not limited thereto. The boundary surface may be curved in a plan view.

According to the present modification, the width w2 of each vapor passage 51 gradually widens with distance from the width change part 56. Therefore, when the working vapor 2a is transferred from one side (heat source region SR side) in the extension direction of the vapor passage 51, the pressure of the working vapor 2a can be particularly decreased in a region away from the heat source region SR. Thus, it is possible to reduce the vapor resistance of the working vapor 2a flowing through the vapor passages 51 and to easily transfer heat along the vapor passages 51.

Particularly, the cross-sectional area of the vapor passage 51 can be increased in a region away from the heat source region SR. Thus, it is possible to reduce blockage of the vapor passage 51 by condensation of the working vapor 2a, so it is possible to cause the working vapor 2a to go around in a wide range. When the condensation region (the outer peripheral length of the vapor passage 51) is expanded, the working vapor 2a can be condensed in a wide range. Thus, a large amount of working liquid 2b that returns to the heat source region SR can be condensed, so it is possible to suppress a decrease in heat transfer performance.

Furthermore, since the width w2 of each vapor passage 51 is made uniform from one side (heat source region SR side) to the width change part 56 in the extension direction of the vapor passage 51, it is possible to smoothly carry the working vapor 2a to the width change part 56 by using the pressure at the time when the working vapor 2a vaporizes. Vapor resistance reduces from the width change part 56 where the pressure at the time of vaporization of the working vapor 2a to the other side in the extension direction of the vapor passage 51. Therefore, it is possible to cause the working vapor 2a to go around to the terminal end of the vapor passage 51. Since the width w2 of each vapor passage 51 is made uniform from one side (heat source region SR side) to the width change part 56 in the extension direction of the vapor passage 51, heat from the device D can be uniformly received by the surface of the vapor passage 51 near the heat source region SR. The working vapor 2a is caused to flow with directivity from the width change part 56 away from the heat source region SR to the terminal end of the vapor passage 51.

In the present modification, the width w2A (see FIG. 3) of each vapor passage 51 at the first main body surface 31a may be changed at the width change part 56 midway in the extension direction of the vapor passage 51. In this case, the width w2A of each vapor passage 51 at the first main body surface 31a may be uniform on one side of the width change part 56 and gradually widen on the other side of the width change part 56 in the extension direction of the vapor passage 51. Alternatively, the width w2B (see FIG. 3) of each vapor passage 51 at the second main body surface 31b may be changed at the width change part 56 midway in the extension direction of the vapor passage 51. In this case, the width w2B of each vapor passage 51 at the second main body surface 31b may be uniform on one side of the width change part 56 and gradually widen on the other side of the width change part 56 in the extension direction of the vapor passage 51.

### Fourth Modification

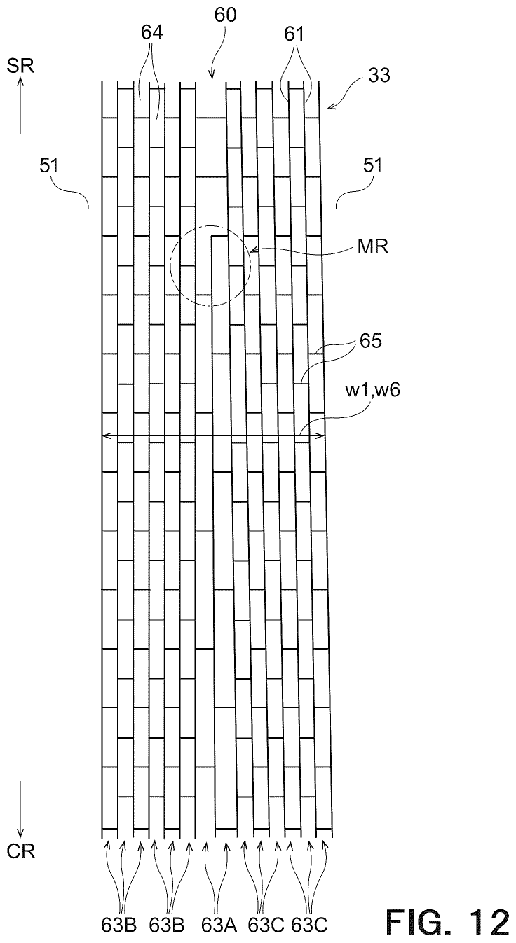

As shown in FIG. 11, the plurality of vapor passages 51 and the plurality of liquid channels 60 radially extend from one side (heat source region SR) in the extension directions of the vapor passages 51 and the liquid channels 60. In FIG. 11, each liquid channel 60 is branched to two first branched liquid channels 60A, 60B at a first branched part 67 located midway in the extension direction of the liquid channel 60. On the other (condensation region CR) side in the extension direction of the liquid channel 60 with respect to the first branched part 67, the liquid channel 60 is branched to the two first branched liquid channels 60A, 60B to be spaced apart from each other. An additional vapor passage 51A may be formed between the adjacent two first branched liquid channels 60A, 60B or the land 33 with no liquid channel 60 may be formed between the adjacent two first branched liquid channels 60A, 60B. When the additional vapor passage 51A is formed between the first branched liquid channels 60A, 60B, a back side channel 76 may be formed on the first main body surface 31a side near the first branched part 67. With the back side channel 76, the vapor passage 51 and the additional vapor passage 51A communicate with each other. The width of the additional vapor passage 51A is gradually widened from one side toward the other side in the extension direction of the additional vapor passage 51A. The vapor passage 51 and the additional vapor passage 51A are coupled to each other by a coupling portion 74. The coupling portion 74 is a thin wall part thinner in thickness than the liquid channel 60. The back side channel 76 is formed on the back side of the coupling portion 74. The coupling portion 74 may also be referred to as a bridge. The liquid channel 60 may be branched to three or more first branched liquid channels 60A, 60B at the first branched part 67. Alternatively, further another branched part may be provided in at least one of the first branched liquid channels 60A, 60B, and the at least one of the first branched liquid channels 60A, 60B may be branched to two or more first branched liquid channels at the other branched part. The width w2 of each vapor passage 51 is uniform in the extension direction of the vapor passage 51; however, the configuration is not limited thereto. The width w2 of each vapor passage 51 may gradually widen with distance from one side (heat source region SR) in the extension direction of the vapor passage 51.

According to the present modification, since the liquid channel 60 is branched to the first branched liquid channels 60A, 60B at the first branched part 67, the working liquid 2b condensed in the condensation region CR can be returned to the heat source region SR side via the first branched liquid channels 60A, 60B. Particularly, when the additional vapor passage 51A is formed between the two first branched liquid channels 60A, 60B, the wide range in the plane of the vapor chamber 1 can be used to transfer heat by using the vapor passage 51 and the additional vapor passage 51A. Thus, it is possible to cause heat from the heat source to go around uniformly in the plane of the vapor chamber 1.

### Fifth Modification

FIG. 12 is a partially enlarged top view that shows the liquid channel 60 in the case where the width w1 of the land 33 and the width w6 of the liquid channel 60 are changed in the longitudinal direction (for example, the examples shown in FIGS. 9 to 11). In FIG. 12, the width w6 of the liquid channel 60 gradually narrows from the lower side toward the upper side in the drawing.

As shown in FIG. 12, as the width w6 of the liquid channel 60 narrows, the protrusions 64 of a plurality of (two in this case) protrusion arrays 63A located on the inner side of the land 33 and the liquid channel 60 in the width direction are integrated, with the result that the number of the protrusion arrays 63 reduces. In other words, as the width w6 of the liquid channel 60 widens, the protrusions 64 of the protrusion arrays 63A located on the inner side of the land 33 and the liquid channel 60 in the width direction are separated, with the result that the number of the protrusion arrays 63 increases. For example, in FIG. 12, the liquid channel 60 includes the plurality of (two) protrusion arrays 63A, a plurality of (six) protrusion arrays 63B, and a plurality of (six) protrusion arrays 63C. Of these, the protrusion arrays 63A are located on the inner side of the land 33 and the liquid channel 60 in the width direction. The protrusion arrays 63B, 63C both are located on the outer side of the land 33 and the liquid channel 60 in the width direction with respect to the protrusion arrays 63A. The width of the protrusion 64 of the protrusion array 63A gradually narrows as the width w6 of the liquid channel 60 gradually narrows. The protrusions 64 of the two protrusion arrays 63A are integrated with each other at a position indicated by the reference sign MR to form the single protrusion array 63A. Alternatively, one of the two protrusion arrays 63A may disappear at the position indicated by the reference sign MR. In this way, the number of protrusion arrays 63 at a position where the width w6 of the liquid channel 60 is wide is greater than the number of protrusion arrays 63 at a position where the width w6 of the liquid channel 60 is narrow. The protrusions 64 of the protrusion arrays 63B, 63C on the outer side in the width direction may be disposed at equal intervals in the width direction of the land 33. The protrusions 64 of the protrusion arrays 63B, 63C on the outer side in the width direction may have a uniform width from one another. In this case, vaporization of the working liquid 2b and recovery of the working liquid 2b can be uniformly performed at any position of the protrusion arrays 63B, 63C. Particularly, the length of each liquid channel communication groove 65 that is in contact with the vapor passage 51 and the interval between the liquid channel communication grooves 65 that are in contact with the vapor passage 51 are made uniform. Therefore, the working liquid 2b condensed in the vapor passage 51 can be uniformly recovered.

According to the present modification, when the protrusions 64 of the two protrusion arrays 63A are integrated on the inner side of the land 33 in the width direction, uneven distribution of the working liquid 2b is less likely to occur in the liquid channel 60. Thus, it is possible to reduce freezing of the working liquid 2b remaining in the liquid channel 60 and, as a result, breakage of the vapor chamber 1.

### Sixth Modification

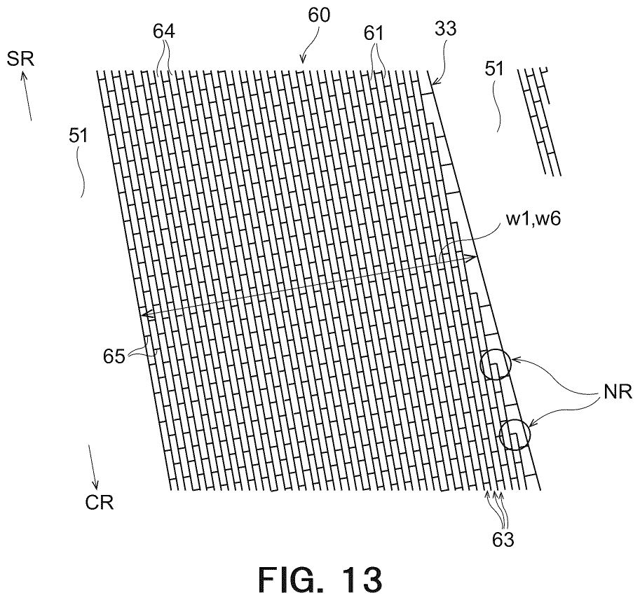

FIG. 13 is a partially enlarged top view that shows the liquid channel 60 in the case where the width w1 of the land 33 and the width w6 of the liquid channel 60 are changed in the longitudinal direction (for example, the examples shown in FIGS. 9 to 11). In FIG. 13, the width w6 of the liquid channel 60 gradually narrows from the lower side toward the upper side.

In FIG. 13, the plurality of liquid channel main stream grooves 61 is located parallel to one another. The widths of the protrusions 64 included in the plurality of protrusion arrays 63 are uniform from one another. In this case, as the width w6 of the liquid channel 60 narrows (widens), the number of protrusion arrays 63 reduces (increases). For example, in FIG. 13, the number of the protrusion arrays 63 located at the outermost side (rightmost side) of the land 33 in the width direction reduces from the lower side toward the upper side. In other words, at a position indicated by the reference sign NR, the protrusion arrays 63 located at the outermost side of the land 33 in the width direction terminate. The configuration is not limited thereto. As the width w6 of the liquid channel 60 narrows, the number of the protrusion arrays 63 located at both sides (both right and left sides) of the land 33 in the width direction may reduce. The thus configured liquid channel 60 is preferably disposed in the middle (transfer part) between the heat source region SR and the condensation region CR.

According to the present modification, it is possible to uniformly transfer the working liquid 2b in the plane of the liquid channel 60, so it is possible to smoothly transfer the working liquid 2b.

### Seventh Modification

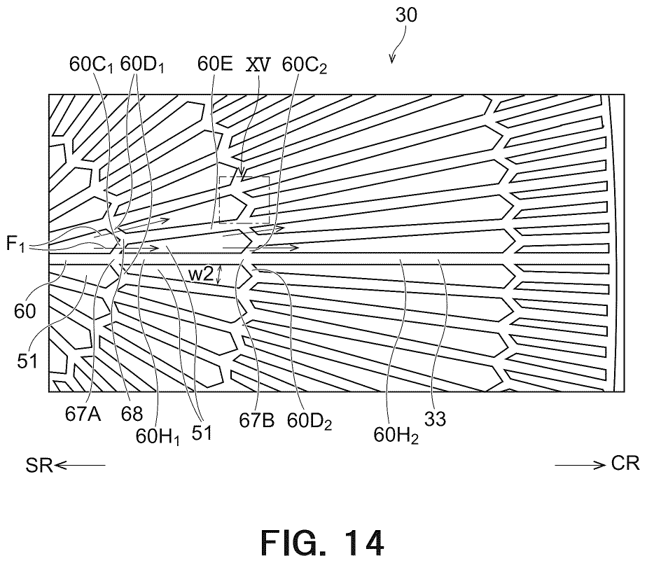

As shown in FIG. 14, the plurality of vapor passages 51 and the plurality of liquid channels 60 radially extend from one side (heat source region SR) in the extension directions of the vapor passages 51 and the liquid channels 60. In this case, each vapor passage 51 and each liquid channel 60 both linearly extend. In FIG. 14, at a first branched part 67A located midway in the extension direction of the liquid channel 60, three first branched liquid channels 60C₁, 60D₁, 60H₁ are branched from the liquid channel 60. On the outer side (condensation region CR side) with respect to the first branched part 67A, the three first branched liquid channels 60C₁, 60D₁, 60H₁ are spaced apart from each other. The first branched liquid channel 60C₁ is connected to another branched liquid channel 60D₁ at a connecting part 68. Another liquid channel 60E extends from the connecting part 68. At a second branched part 67B located midway in the extension direction of the first branched liquid channel 60H₁, three second branched liquid channels 60C₂, 60D₂, 60H₂ are further branched from the first branched liquid channel 60H₁. In this way, repeatedly, the branched liquid channels 60C₁, 60D₁, 60C₂, 60D₂ are branched from the branched liquid channels 60H₁, 60H₂, and the branched liquid channels 60C₁, 60C₂ are connected to the other branched liquid channels 60D₁, 60D₂ to form other liquid channels 60E. Thus, the branched liquid channels 60H₁, 60H₂ and the other liquid channels 60E radially extend.

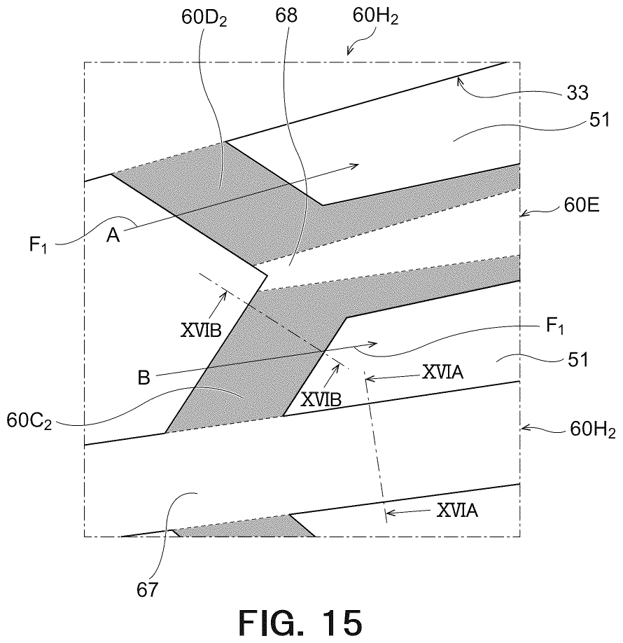

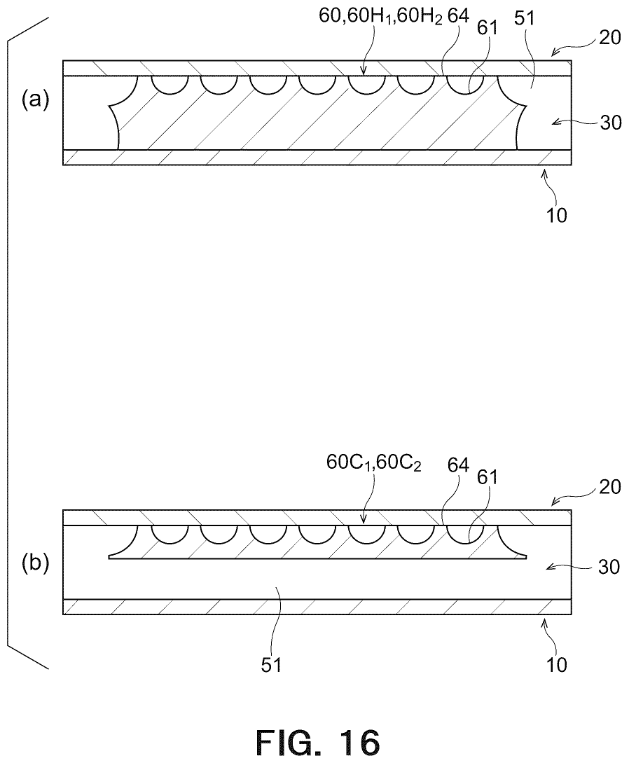

FIG. 15 is a partially enlarged view of FIG. 14 (an enlarged view of portion XV in FIG. 14). FIGS. 16(a) and 16(b) are partially sectional views of FIG. 15 (a sectional view taken along the line XVIA-XVIA and a sectional view taken along the line XVIB-XVIB in FIG. 15).

As shown in FIGS. 15, 16(a), and 16(b), the branched liquid channels 60C₁, 60D₁, 60C₂, 60D₂ are thinned from the back side. In the other liquid channel 60E, part of the region located adjacent to the connecting part 68 is thinned from the back side. On the other hand, the liquid channel 60 and the branched liquid channels 60H₁, 60H₂ are not thinned from the back side. The vapor passage 51 is formed at each of the thinned portions of the branched liquid channels 60C₁, 60D₁, 60C₂, 60D₂, and the other liquid channels 60E. In FIG. 15, the thinned portions are indicated in gray.

In FIGS. 14 and 15, the flow of the working vapor 2a in each vapor passage 51 is indicated by the arrow F1. As shown in FIGS. 14 and 15, the vapor passage 51 is branched into two at the connecting part 68. In this case, the width w2 of each vapor passage 51 gradually widens from one side toward the other side in the extension direction of the vapor passage 51. Near the connecting part 68, the two vapor passages 51 have a shape line-symmetric to the other liquid channel 60E. Thus, the working vapor 2a can be equally flowed to the two branched vapor passages 51, so thermal uniformity is possible.

According to the present modification, each of the liquid channels 60, 60E, the branched liquid channels 60H₁, 60H₂, and the vapor passage 51 is branched and radially extends from one side (heat source region SR) toward the outer side (condensation region CR) in the extension direction of a corresponding one of the liquid channels 60, 60E, the branched liquid channels 60H₁, 60H₂, and the vapor passage 51. Thus, each vapor passage 51 and each of the liquid channels 60, 60E and the branched liquid channels 60H₁, 60H₂ can be relatively narrowed. Therefore, the flexibility of arrangement of the vapor passage 51, the liquid channels 60, 60E, and the branched liquid channels 60H₁, 60H₂ is increased, so the vapor passage 51, the liquid channels 60, 60E, and the branched liquid channels 60H₁, 60H₂ can be disposed with an efficient ratio. Where the width of each of the liquid channels 60, 60E and the branched liquid channels 60H₁, 60H₂ is one, the width of the vapor passage 51 may be greater than or equal to 0.2 and less than or equal to five. Furthermore, according to the present modification, since the vapor passage 51 linearly extends from one side (heat source region SR) in the extension direction of the vapor passage 51, it is possible to reduce resistance that the working vapor 2a receives in the vapor passage 51. Furthermore, according to the present modification, since the liquid channel 60 linearly extends from one side (heat source region SR) in the extension direction of the liquid channel 60, it is possible to suppress pushing back of the returning working liquid 2b by the working vapor 2a.

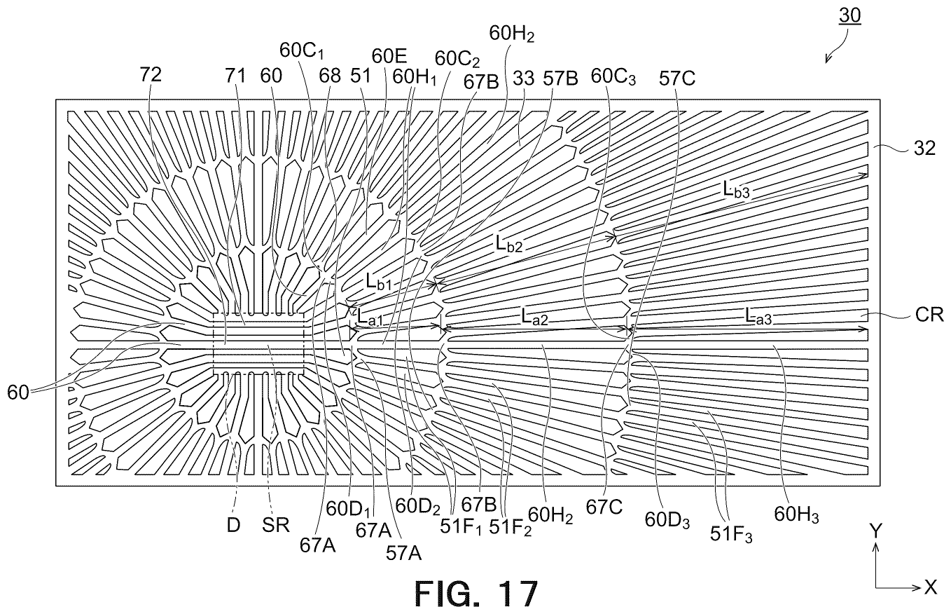

FIG. 17 is a reduced view of FIG. 14 and shows the wick sheet 30 in a range wider than that of FIG. 14.

As shown in FIG. 17, the plurality of liquid channels 60 radially extends over all the region in the circumferential direction about part of the region (heat source region SR). Extension lines of the plurality of liquid channels 60 may intersect at a single point. The single point may be in the heat source region SR. In this case, heat in a small region may be spread toward the entire part of the vapor chamber 1.

As shown in FIG. 17, at the first branched part 67A, three first branched liquid channels 60C₁, 60D₁, 60H₁ are branched from the liquid channel 60. At the second branched part 67B, three second branched liquid channels 60C₂, 60D₂, 60H₂ are branched from the first branched liquid channel 60H₁. Furthermore, at the third branched part 67C, three third branched liquid channels 60C₃, 60D₃, 60H₃ are branched from the second branched liquid channel 60H₂.

The first branched part 67A is closer to one side (heat source region SR) of the first branched liquid channel 60H₁ in the extension direction than the second branched part 67B. The second branched part 67B is closer to one side (heat source region SR) of the second branched liquid channel 60H₂ in the extension direction than the third branched part 67C. A branched part may be further provided on the other side of the third branched part 67C.

The length La₁ of the first branched liquid channel 60H₁ in the extension direction from the first branched part 67A to the second branched part 67B is shorter than the length La₂ of the second branched liquid channel 60H₂ in the extension direction from the second branched part 67B to the third branched part 67C. Similarly, the length La₂ of the second branched liquid channel 60H₂ in the extension direction from the second branched part 67B to the third branched part 67C may be shorter than the length La₃ of the third branched liquid channel 60H₃ in the extension direction from the third branched part 67C to the terminal end of the third branched liquid channel 60H₃. In other words, the distance between the branched parts increases with distance from the heat source region SR. Thus, the width of the vapor passage 51 can be set so as not to exceed a certain value. Therefore, when pressure is applied in the thickness direction of the vapor chamber 1, deformation of the vapor chamber 1 is suppressed. A region away from the heat source region SR relatively tends to decrease in vapor pressure. When the number of the branched liquid channels 60C₁, 60D₁, 60C₂, 60D₂, 60C₃, 60D₃ disposed in the region away from the heat source region SR is reduced, vapor resistance is reduced, with the result that the working vapor 2a (heat) can be more easily conveyed farther. Furthermore, when the number of branched parts is reduced, it is possible to suppress a reduction in the vapor pressure of the working vapor 2a below the vapor resistance. Alternatively, it is possible to suppress a reduction in the vapor pressure of the working vapor 2a more than necessary. Thus, it is possible to cause the working vapor 2a to go around to the terminal end of the vapor passage.

The plurality of first branched parts 67A may be disposed on the same circle. The plurality of second branched parts 67B may be disposed on the same circle. The plurality of third branched parts 67C may be disposed on the same circle. The circle on which the first branched parts 67A are disposed, the circle on which the second branched parts 67B are disposed, and the circle on which the third branched parts 67C are disposed may be concentric to one another. The plurality of third branched liquid channels 60H₃ may extend to the frame 32. In this case, the pressure of the working vapor 2a is substantially the same at a position at substantially the same distance from the heat source region SR. Therefore, it is possible to reduce a situation in which the working vapor 2a more easily flows to part of the region of the wick sheet 30.

The number of the branched parts 67A, 67B, 67C may be varied in the short-side direction of the wick sheet 30 and the longitudinal direction of the wick sheet 30. Thus, heat can be more easily transferred in a direction in which the number of the branched parts 67A, 67B, 67C is smaller. For example, in FIG. 17, it is possible to efficiently transfer the working vapor 2a to the frame 32 located in the short-side direction of the wick sheet 30. The number of the branched parts 67A, 67B, 67C from the heat source region SR to the frame 32 may be varied between the liquid channel 60 extending in one direction and the liquid channel 60 extending in the other direction. In this case, since the number of the branched parts 67A, 67B, 67C can be changed according to the position of the heat source region SR, the flexibility of the position of the heat source region SR increases.

As shown in FIG. 17, the plurality of vapor passages 51 radially extends over all the region in the circumferential direction about part of the region (heat source region SR). As shown in FIG. 17, at the fourth branched part 57A, two first branched vapor passages 51F₁, 51F₁ are branched from the vapor passage 51. At the fifth branched part 57B, two second branched vapor passages 51F₂, 51F₂ are branched from the first branched vapor passage 51F₁. Furthermore, at the sixth branched part 57C, two third branched vapor passages 51F₃, 51F₃ are branched from the vapor passage 51.

The fourth branched part 57A is closer to one side (heat source region SR) of the first branched vapor passage 51F₁ in the extension direction than the fifth branched part 57B. The fifth branched part 57B is closer to one side (heat source region SR) of the second branched vapor passage 51F₂ in the extension direction than the sixth branched part 57C. A branched part may be further provided on the other side of the sixth branched part 57C. The fourth branched part 57A, the fifth branched part 57B, and the sixth branched part 57C may be respectively placed at the same positions as the connecting parts 68.

The length Lb₁ of the first branched vapor passage 51F₁ in the extension direction from the fourth branched part 57A to the fifth branched part 57B may be shorter than the length Lb₂ of the second branched vapor passage 51F₂ in the extension direction from the fifth branched part 57B to the sixth branched part 57C. Similarly, the length Lb₂ of the second branched vapor passage 51F₂ in the extension direction from the fifth branched part 57B to the sixth branched part 57C may be shorter than the length Lb₃ of the third branched vapor passage 51F₃ in the extension direction from the sixth branched part 57C to the third branched vapor passage 51F₃. In other words, the distance between the branched parts may increase with distance from the heat source region SR. Thus, when the number of branched parts disposed in a region away from the heat source region SR is reduced, it is possible to suppress a reduction in the vapor pressure of the working vapor 2a in the region away from the heat source region SR. Alternatively, it is possible to suppress a reduction in the vapor pressure of the working vapor 2a more than necessary. Thus, it is possible to cause the working vapor 2a to go around to the terminal end of the vapor passage.

The plurality of fourth branched parts 57A may be disposed on the same circle. The plurality of fifth branched parts 57B may be disposed on the same circle. The plurality of sixth branched parts 57C may be disposed on the same circle. The circle on which the fourth branched parts 57A are disposed, the circle on which the fifth branched parts 57B are disposed, and the circle on which the sixth branched parts 57C are disposed may be concentric to one another. The plurality of third branched vapor passages 51F₃ may extend to the frame 32. In this case, the pressure of the working vapor 2a is substantially the same at a position at substantially the same distance from the heat source region SR. Therefore, it is possible to reduce a situation in which the working vapor 2a more easily flows to part of the region of the wick sheet 30.

The number of the branched parts 57A, 57B, 57C may be varied in the short-side direction of the wick sheet 30 and the longitudinal direction of the wick sheet 30. Thus, heat can be more easily transferred in a direction in which the number of the branched parts 57A, 57B, 57C is smaller.

As shown in FIG. 17, the plurality of liquid channels 60 is coupled to one another in the heat source region SR. A plurality of heat source internal liquid channels 72 is disposed in the heat source region SR. The plurality of heat source internal liquid channels 72 may be disposed parallel to each other. The lands 33 are respectively coupled to both ends in the longitudinal direction of the heat source internal liquid channel 72 located adjacent to the center of the heat source region SR. The lands 33 are respectively coupled to both ends in the longitudinal direction of the heat source internal liquid channel 72 located at the outermost side of the heat source region SR, and the plurality of lands 33 is coupled midway in the longitudinal direction of that heat source internal liquid channel 72. A heat source internal vapor passage 71 is disposed between the heat source internal liquid channels 72 adjacent to each other. The plurality of heat source internal vapor passages 71 may be disposed parallel to each other. The vapor passages 51 are respectively connected to both ends in the longitudinal direction of each heat source internal vapor passage 71.

In this way, the shape of the liquid channels 60 inside the heat source region SR differs from the shape of the liquid channels 60 that radially extend outside the heat source region SR. The plurality of liquid channels 60 may radially extend from the outer circumference of the heat source region SR. As shown in FIG. 17, the heat source region SR may have a quadrangular shape, and the plurality of liquid channels 60 may radially extend from each side of the quadrangular shape. Thus, the structure of the heat source internal liquid channels 72 can be made suitable for a heat source inside the heat source region SR. As shown in FIG. 17, when the plurality of heat source internal liquid channels 72 is disposed parallel to each other, the area in which the working liquid 2b vaporizes can be ensured as compared to when the liquid channels 60 radially extend from a single point. Thus, the vapor resistance of the working vapor 2a can be reduced, so the working liquid 2b can be more easily vaporized.

In the present modification, the width w2A (see FIG. 3) of the vapor passage 51 at the first main body surface 31a may gradually widen from one side toward the other side in the extension direction of the vapor passage 51. Alternatively, the width w2B (see FIG. 3) of the vapor passage 51 at the second main body surface 31b may gradually widen from one side toward the other side in the extension direction of the vapor passage 51.

### Eighth Modification

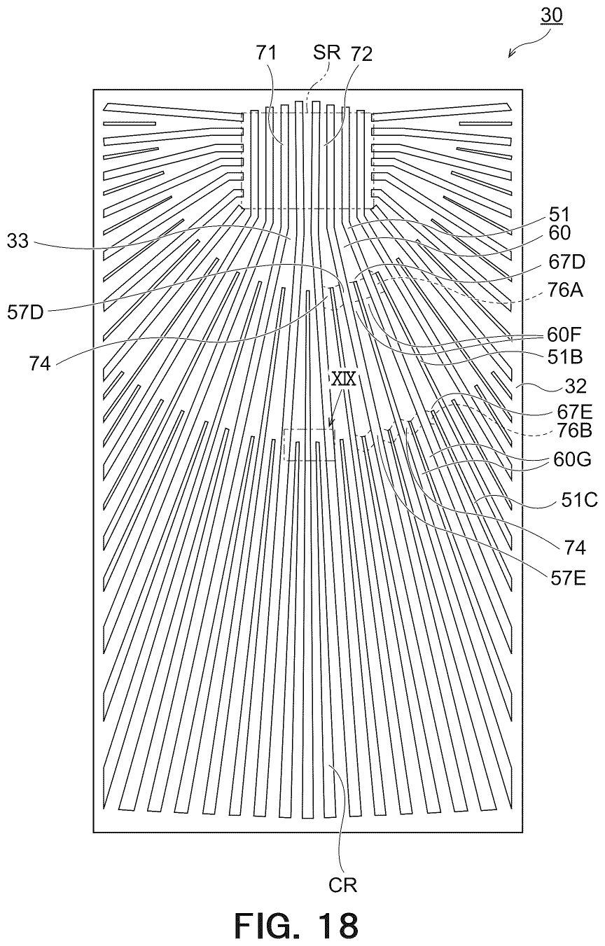

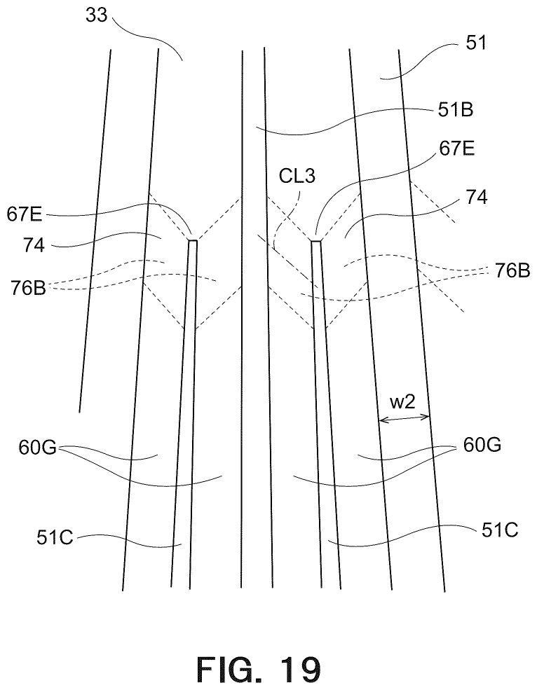

As shown in FIGS. 18 and 19, the plurality of vapor passages 51 and the plurality of liquid channels 60 radially extend from one side (heat source region SR) toward the outer side (condensation region CR) in the extension directions of the vapor passages 51 and the liquid channels 60. Each liquid channel 60 is branched to two first branched liquid channels 60F, 60F at a first branched part 67D located midway in the extension direction of the liquid channel 60. In other words, on the other (condensation region CR) side in the extension direction of the liquid channel 60 with respect to the first branched part 67D, the liquid channel 60 is branched to the two first branched liquid channels 60F, 60F to be spaced apart from each other. An additional vapor passage 51B may be formed between the adjacent two first branched liquid channels 60F, 60F. A back side channel 76A may be formed on the first main body surface 31a side near the first branched part 67D. The vapor passage 51 and the additional vapor passage 51B are coupled to each other by a coupling portion 74. The coupling portion 74 is a thin wall part thinner in thickness than the liquid channel 60. The back side channel 76A is formed on the back side of the coupling portion 74. The coupling portion 74 may also be referred to as a bridge. With the back side channel 76A, the vapor passage 51 and the additional vapor passage 51B communicate with each other. The liquid channel 60 may be branched to three or more first branched liquid channels 60F at the first branched part 67D.

Each first branched liquid channel 60F is branched to two second branched liquid channels 60G, 60G at a second branched part 67E located midway in the extension direction of the first branched liquid channel 60F. In other words, on the other (condensation region CR) side in the extension direction of the first branched liquid channel 60F with respect to the second branched part 67E, the first branched liquid channel 60F is branched to the two second branched liquid channels 60G, 60G to be spaced apart from each other. An additional vapor passage 51C is formed between the adjacent two second branched liquid channels 60G, 60G. A back side channel 76B may be formed on the first main body surface 31a side near the second branched part 67E. The vapor passage 51 and the additional vapor passage 51C are coupled to each other by a coupling portion 74. Alternatively, the additional vapor passage 51B and the additional vapor passage 51C are coupled to each other by a coupling portion 74. The coupling portion 74 is a thin wall part thinner in thickness than the liquid channel 60. The back side channel 76B is formed on the back side of the coupling portion 74. The coupling portion 74 may also be referred to as a bridge. With the back side channel 76B, the vapor passage 51 and the additional vapor passage 51C communicate with each other. Alternatively, with the back side channel 76B, the additional vapor passage 51B and the additional vapor passage 51C communicate with each other. The first branched liquid channel 60F may be branched to three or more second branched liquid channels at the second branched part 67E.

At another branched part located on the other side in the extension direction of the second branched liquid channel 60G with respect to the second branched part 67E, the second branched liquid channel 60G may be further branched to two or more third branched liquid channels. For example, the second branched liquid channel 60G may be branched to a plurality of third branched liquid channels at a third branched part (not shown) located on the other side in the extension direction of the second branched liquid channel 60G with respect to the second branched part 67E. In this case, the length of the first branched liquid channel 60F in the extension direction from the first branched part 67D to the second branched part 67E is shorter than the length of the second branched liquid channel 60G in the extension direction from the second branched part 67E to the third branched part.

The vapor passage 51 is branched to three first branched vapor passages at the fourth branched part 57D located midway in the extension direction of the vapor passage 51. In this case, the three first branched vapor passages are made up of a portion located on the other side in the extension direction of the vapor passage 51 with respect to the fourth branched part 57D in the vapor passage 51, and two back side channels 76A, 76A. A portion located on the other side in the extension direction of the vapor passage 51 with respect to the fourth branched part 57D in the vapor passage 51 is branched to three second branched vapor passages at the fifth branched part 57E located midway in the extension direction of the portion. In this case, the three first branched vapor passages are made up of a portion located on the other side in the extension direction of the vapor passage 51 with respect to the fifth branched part 57E in the vapor passage 51, and two back side channels 76B, 76B. A portion located on the other side in the extension direction of the vapor passage 51 with respect to the fifth branched part 57E in the vapor passage 51 may be further branched to a plurality of third branched vapor passages at a sixth branched part (not shown) located midway in the extension direction of the portion. In this case, the length of the third branched vapor passage in the extension direction from the fifth branched part 57E to the sixth branched part may be shorter than the length of the second branched vapor passage in the extension direction from the fourth branched part 57D to the fifth branched part 57E.

A plurality of heat source internal liquid channels 72 is disposed in the heat source region SR. The plurality of heat source internal liquid channels 72 may be disposed parallel to each other. The lands 33 are respectively coupled to one end in the longitudinal direction of the heat source internal liquid channel 72 located adjacent to the center of the heat source region SR. The land 33 is coupled to one end in the longitudinal direction of the heat source internal liquid channel 72 located at the outermost side of the heat source region SR, and the plurality of lands 33 is coupled midway in the longitudinal direction of that heat source internal liquid channel 72. The heat source internal vapor passage 71 is disposed between the heat source internal liquid channels 72 adjacent to each other. The plurality of heat source internal vapor passages 71 may be disposed parallel to each other. The vapor passage 51 is connected to one end in the longitudinal direction of each heat source internal vapor passage 71.

The vapor passage 51 connected to the heat source internal vapor passage 71 continuously extends to the frame 32 on the condensation region CR side. The additional vapor passage 51B communicates with the vapor passage 51 via the back side channel 76A. The additional vapor passage 51C communicates with the vapor passage 51 via the back side channel 76B. In this way, with the vapor passage 51 through which the working vapor 2a more easily flows than the additional vapor passages 51B, 51C, heat can be quickly transferred to the condensation region CR side in the course in which the temperature of the heat source region SR increases. When the temperature of the heat source region SR further increases, a large amount of heat (working vapor 2a) can be conveyed to the condensation region CR side by the additional vapor passages 51B, 51C.

Furthermore, when the vapor passage 51 is branched to the additional vapor passages 51B, 51C, the branched liquid channels 60F and the additional vapor passages 51B communicate in a wider range, and the branched liquid channels 60G and the additional vapor passages 51C communicate in a wider range. Therefore, the working liquid 2b flocculated in the additional vapor passages 51B or the additional vapor passages 51C can be quickly taken into the branched liquid channels 60F or the branched liquid channels 60G. In this case, the amount of working liquid 2b returning to the heat source region SR increases, so it is possible to suppress a decrease in heat transfer performance.

FIG. 19 is a partially enlarged view of FIG. 18 and is an enlarged view of portion XIX in FIG. 18. FIG. 19 shows an area around the second branched part 67E. As shown in FIG. 19, the width w2 of the vapor passage 51 may be uniform in the extension direction of the vapor passage 51. In this case, the area of the liquid channel 60 can be increased, so the storage amount of the working liquid 2b can be increased. Thus, it is possible to suppress shortage of the working liquid 2b when the temperature of the device D rapidly increases. The width w2A (see FIG. 3) of the vapor passage 51 at the first main body surface 31a may be uniform in the extension direction of the vapor passage 51. Alternatively, the width w2B (see FIG. 3) of the vapor passage 51 at the second main body surface 31b may be uniform in the extension direction of the vapor passage 51.

Alternatively, the width w2 of the vapor passage 51 may change from midway in the extension direction of the vapor passage 51 and gradually widen from one side toward the other side in the extension direction of the vapor passage 51. Thus, particularly, the cross-sectional area of the vapor passage 51 can be increased in a region away from the heat source region SR. As a result, it is possible to reduce blockage of the vapor passage 51 by condensation of the working vapor 2a, so it is possible to cause the working vapor 2a to go around in a wide range. When the condensation region (the outer peripheral length of the vapor passage 51) is expanded, the working vapor 2a can be condensed in a wide range. Thus, a large amount of working liquid 2b that returns to the heat source region SR can be condensed, so it is possible to suppress a decrease in heat transfer performance. The width w2A (see FIG. 3) of each vapor passage 51 at the first main body surface 31a may change from midway in the extension direction of the vapor passage 51 and gradually widen from one side toward the other side in the extension direction of the vapor passage 51. Alternatively, the width w2B (see FIG. 3) of each vapor passage 51 at the second main body surface 31b may change from midway in the extension direction of the vapor passage 51 and gradually widen from one side toward the other side in the extension direction of the vapor passage 51.

As shown in FIG. 19, a center line CL3 in the width direction of the back side channel 76B is inclined so as to leave from the heat source region SR toward the second branched liquid channel side. Thus, it is possible to reduce the vapor resistance of the working vapor 2a flowing through the back side channel 76B. The back side channel 76A may also be configured similarly to the back side channel 76B.

### Ninth Modification

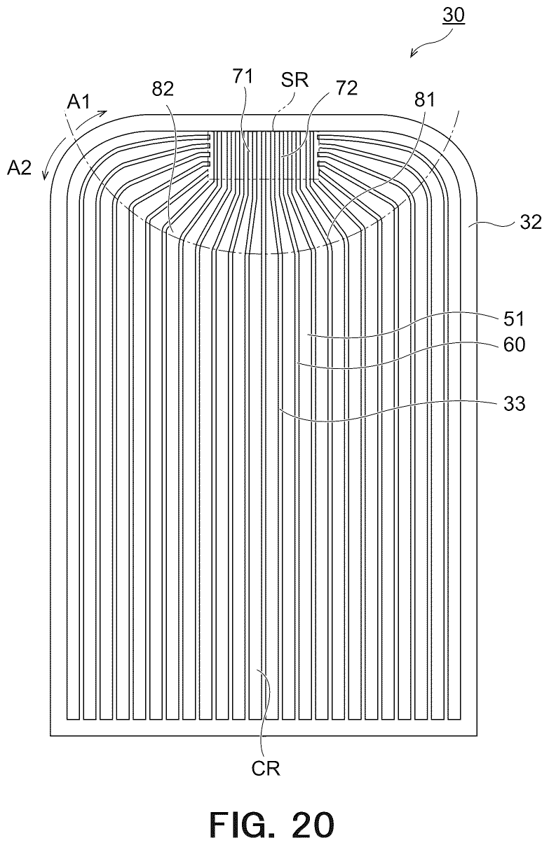

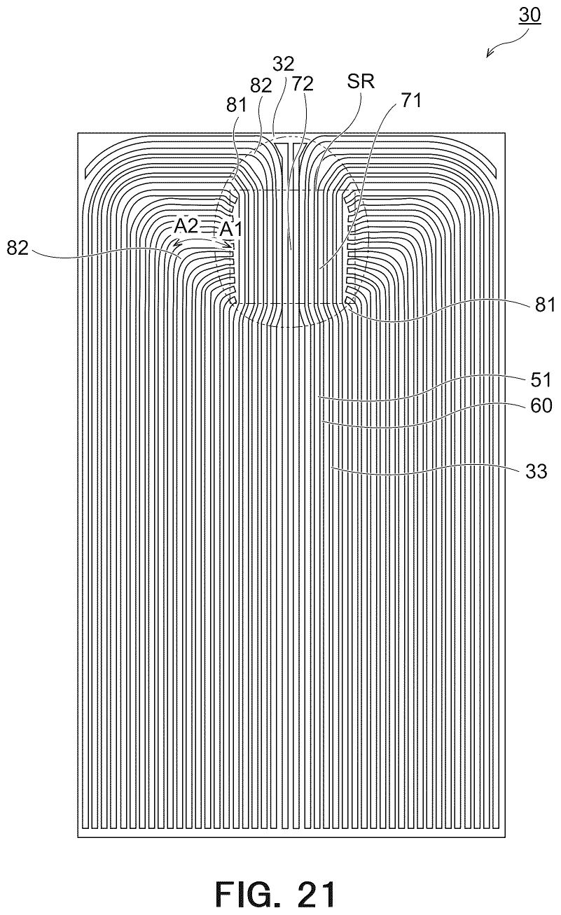

As shown in FIG. 20, the wick sheet 30 includes a first region A1 and a second region A2. The first region A1 is a region in which the vapor passages 51 and the liquid channels 60 radially extend. The second region A2 is a region in which the vapor passages 51 and the liquid channels 60 linearly extend in the same direction.

As shown in FIG. 20, in the first region A1, the plurality of vapor passages 51 radially extends from the heat source region SR to a vapor passage direction change part 82. Each vapor passage 51 is bent at the vapor passage direction change part 82. The vapor passage 51 may be bent or curved at the vapor passage direction change part 82. The second region A2 is present on the other (condensation region CR) side with respect to the vapor passage direction change part 82. In the second region A2, the plurality of vapor passages 51 is disposed parallel to each other in the same direction.

Similarly, in the first region A1, the plurality of liquid channels 60 radially extends from the heat source region SR to a liquid channel direction change part 81. Each liquid channel 60 is bent at the liquid channel direction change part 81. The liquid channel 60 may be linearly bent or curved in a curved shape at the liquid channel direction change part 81. The second region A2 is present on the other (condensation region CR) side with respect to the liquid channel direction change part 81. In the second region A2, the plurality of liquid channels 60 is disposed parallel to each other.

According to the example shown in FIG. 20, no branched part is present in the vapor passages 51 or the liquid channels 60. Therefore, it is possible to suppress an increase in the vapor resistance of the working vapor 2a flowing through the vapor passage 51. Thus, it is possible to smoothly cause the working vapor 2a to go around to the terminal end, so heat transfer performance is enhanced. The width of each vapor passage 51 in the second region A2 and the width of each liquid channel 60 in the second region A2 can be set to selected values.

As shown in FIG. 21, in the first region A1, each of the plurality of vapor passages 51 and the plurality of liquid channels 60 may radially extend over all the region in the circumferential direction about the heat source region SR. Each liquid channel 60 is bent at the liquid channel direction change part 81. In the second region A2, the plurality of liquid channels 60 is disposed parallel to each other in the same direction. Each vapor passage 51 is bent at the vapor passage direction change part 82. In the second region A2 side, the plurality of vapor passages 51 is disposed parallel to each other in the same direction. A plurality of the vapor passage direction change parts 82 may be provided in one vapor passage 51. A plurality of the liquid channel direction change parts 81 may be provided in one liquid channel 60.

According to the example shown in FIG. 21, even when the heat source region SR is away from the frame 32, it is possible to cause the working vapor 2a to go around in various directions. Thus, it is possible to dissipate heat from the entire surface of the vapor chamber 1 or transfer heat to the entire surface of the vapor chamber 1.

### Tenth Modification

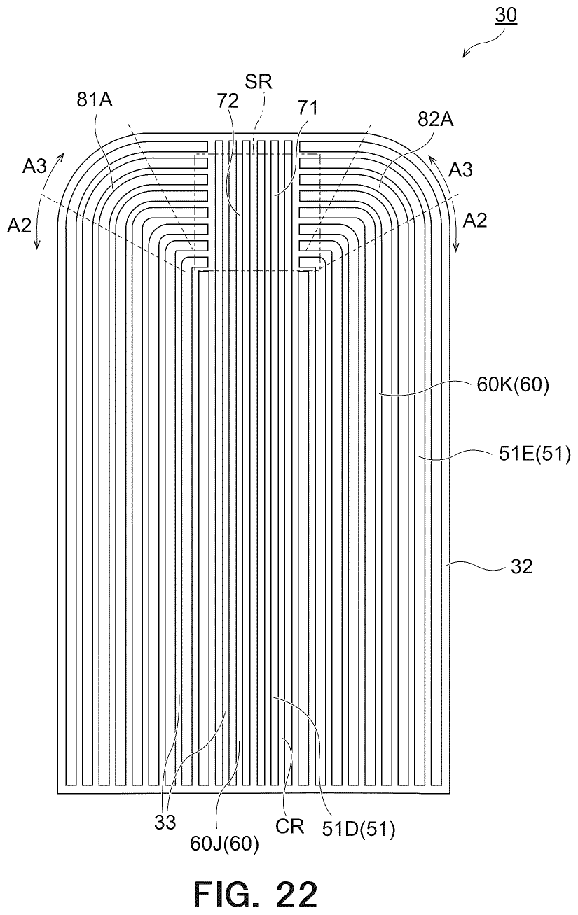

As shown in FIG. 22, the wick sheet 30 includes a third region A3 and a second region A2. The third region A3 is a region in which the vapor passages 51 and the liquid channels 60 extend so as to be curved. The second region A2 is a region in which the vapor passages 51 and the liquid channels 60 linearly extend in the same direction.

As shown in FIG. 22, the plurality of vapor passages 51 includes first vapor passages 51D and second vapor passages 51E. Each first vapor passage 51D linearly extends from the heat source region SR. Each second vapor passage 51E extends from the heat source region SR and is bent at a vapor passage width change part 82A located in the third region A3. Parts of the second vapor passages 51E, located in the second region A2, extend parallel to the first vapor passages 51D. The width of each of the first vapor passage 51D and the second vapor passage 51E is defined similarly to the width w2 of the above-described vapor passage 51.

When the width of the vapor passage 51, the first vapor passage 51D, or the second vapor passage 51E is constant and remains unchanged in the extension direction, the width at a selected position in the extension direction of a corresponding one of the vapor passages 51, 51D, 51E is defined as “the width of the vapor passage”. When the width of the vapor passage 51, the vapor passage 51D, or the vapor passage 51E varies in the extension direction, a mean of a corresponding one of the vapor passages 51, 51D, 51E is defined as “the width of the vapor passage”, and the width of the vapor passage is compared.

In this case, a mean of the width of one of the vapor passages 51, 51D, 51E is obtained as follows.
(1) Initially, the plane area of a target one of the vapor passages 51, 51D, 51E is calculated. When there is CAD data of a target one of the vapor passages 51, 51D, 51E, the planar area of a corresponding one of the vapor passages 51, 51D, 51E is calculated in accordance with the CAD data. When obtained from a real one of the vapor passages 51, 51D, 51E, the planar area of a corresponding one of the vapor passages 51, 51D, 51E can be calculated in accordance with the number of pixels of an image of the corresponding one of the vapor passages 51, 51D, 51E, taken in with a two-dimensional measuring machine.
(2) Subsequently, for the target one of the vapor passages 51, 51D, 51E, the length of the center line in the width direction from a heat source region-side end to a condensation region-side end is obtained.
(3) A value obtained by dividing the planar area obtained in (1) by the length obtained in (2) is defined as a mean of the width of the corresponding one of the vapor passages 51, 51D, 51E.

The width w2A (see FIG. 3) of each of the vapor passages 51, 51D, 51E at the first main body surface 31a and the width w2B (see FIG. 3) of each of the vapor passages 51, 51D, 51E at the second main body surface 31b can also be similarly obtained.

Similarly, the plurality of liquid channels 60 includes first liquid channels 60J and second liquid channels 60K. Each first liquid channel 60J linearly extends from the heat source region SR. Each second liquid channel 60K extends from the heat source region SR and is bent at a liquid channel direction change part 81A located in the third region A3. Parts of the second liquid channel 60K, located in the second region A2, extend parallel to the first liquid channels 60J. The width of each of the first liquid channel 60J and the second liquid channel 60K is similarly defined as the width w6 of the above-described liquid channel 60.

When the width of the liquid channel 60, the first liquid channel 60J, or the second liquid channel 60K is constant and remains unchanged in the extension direction, the width at a selected position in the extension directions of a corresponding one of the liquid channels 60, 60J, 60K is defined as “the width of the liquid channel”. When the width of the liquid channel 60, the liquid channel 60J, or the liquid channel 60K varies in the extension direction, a mean of a corresponding one of the liquid channels 60, 60J, 60K is defined as “the width of the liquid channel”, and the width of the liquid channel is compared.

In this case, a mean of the width of one of the liquid channels 60, 60J, 60K is obtained as follows.
(1) Initially, the plane area of a target one of the liquid channels 60, 60J, 60K is calculated. When there is CAD data of a target one of the liquid channels 60, 60J, 60K, the planar area of a corresponding one of the liquid channels 60, 60J, 60K is calculated in accordance with the CAD data. When obtained from a real one of the liquid channels 60, 60J, 60K, the planar area of a corresponding one of the liquid channels 60, 60J, 60K can be calculated in accordance with the number of pixels of an image of the corresponding one of the liquid channels 60, 60J, 60K, taken in with a two-dimensional measuring machine.
(2) Subsequently, for the target one of the liquid channels 60, 60J, 60K, the length of the center line in the width direction from a heat source region-side end to a condensation region-side end is obtained.
(3) A value obtained by dividing the planar area obtained in (1) by the length obtained in (2) is defined as a mean of the width of the corresponding one of the liquid channels 60, 60J, 60K.

The width of each of the liquid channels 60, 60J, 60K at the first main body surface 31a and the width of each of the liquid channels 60, 60J, 60K at the second main body surface 31b are also similarly obtained.

In FIG. 22, the width of the second vapor passage 51E changes midway in the extension direction of the second vapor passage 51E. Specifically, in the third region A3, the width of the second vapor passage 51E gradually widens from one side (heat source region SR side) toward the other side (condensation region CR side) in the extension direction of the second vapor passage 51E. In this case, the width of the second vapor passage 51E is wider at a portion located on the other side (condensation region CR side) in the extension direction of the second vapor passage 51E with respect to a vapor passage width change part 82A than at a portion located on one side (heat source region SR side) in the extension direction of the second vapor passage 51E with respect to the vapor passage width change part 82A. In the third region A3, the width of the second vapor passage 51E at the first main body surface 31a may gradually widen from one side toward the other side in the extension direction of the second vapor passage 51E. Alternatively, in the third region A3, the width of the second vapor passage 51E at the second main body surface 31b may gradually widen from one side toward the other side in the extension direction of the second vapor passage 51E. The width of the first vapor passage 51D may be uniform in the extension direction of the first vapor passage 51D. The width of the second vapor passage 51E and the width of the first vapor passage 51D may be different from each other. For example, in the second vapor passage 51E, the width of a portion located on the other side in the extension direction of the second vapor passage 51E with respect to the vapor passage width change part 82A may be wider than the width of the first vapor passage 51D.

The width of the second liquid channel 60K may be uniform or may be changed midway in the extension direction of the second liquid channel 60K. When the width of the second liquid channel 60K varies, the width of the second liquid channel 60K may gradually widen from one side (heat source region SR side) toward the other side (condensation region CR side) in the extension direction of the second liquid channel 60K in the third region A3. In this case, the width of the second liquid channel 60K is wider at a portion located on the other side (condensation region CR side) in the extension direction of the second liquid channel 60K with respect to the liquid channel direction change part 81A than at a portion located on one side (heat source region SR side) in the extension direction of the second liquid channel 60K with respect to the liquid channel direction change part 81A. In the third region A3, the width of the second liquid channel 60K at the first main body surface 31a may gradually widen from one side toward the other side in the extension direction of the second liquid channel 60K. Alternatively, in the third region A3, the width of the second liquid channel 60K at the second main body surface 31b may gradually widen from one side toward the other side in the extension direction of the second liquid channel 60K. The width of the first liquid channel 60J may be uniform in the extension direction of the first liquid channel 60J. The width of the second liquid channel 60K and the width of the first liquid channel 60J may be different from each other. For example, in the second liquid channel 60K, the width of a portion located on the other side in the extension direction of the second liquid channel 60K with respect to the liquid channel direction change part 81A may be wider than the width of the first liquid channel 60J.

According to the example shown in FIG. 22, the width of the second vapor passage 51E of which the length in the extension direction is long is wider than the width of the first vapor passage 51D of which the length in the extension direction is short. Alternatively, the width of the second vapor passage 51E at the first main body surface 31a or the width of the second vapor passage 51E at the second main body surface 31b, of which the length in the extension direction is long, is wider than the width of the first vapor passage 51D at the first main body surface 31a or the width of the first vapor passage 51D at the second main body surface 31b, of which the length in the extension direction is short. Thus, even when the distance from the heat source region SR is long, the vapor resistance of the working vapor 2a can be reduced. Therefore, the working vapor 2a can be quickly sent to the terminal end by using the second vapor passage 51E of which the length is long without delay from the working vapor 2a that passes through the first vapor passage 51D of which the length is short. Thus, even when the lengths of the plurality of vapor passages 51 are varied, it is possible to achieve thermal uniformity in the entire region of the vapor chamber 1.

Three or more vapor passages 51D, 51E may be disposed, and the length of each of the vapor passages 51D, 51E in the extension direction may be varied from each other. In other words, the lengths of the vapor passages 51D, 51E may include three or more levels. In this case, the width may increase as the length of one of the vapor passages 51D, 51E in the extension direction increases. In other words, the width of each of the vapor passages 51D, 51E may have three or more levels according to the length of a corresponding one of the vapor passages 51D, 51E. Thus, the width of each of the vapor passages 51D, 51E that send the working vapor 2a to a portion of which the distance from the heat source region SR is long can be widened to reduce the vapor resistance of the working vapor 2a flowing through the vapor passages 51D, 51E. As a result, it is possible to achieve thermal uniformity in the entire region of the vapor chamber 1.

As in the case of the example shown in FIG. 22, when there is a region in which the second vapor passage 51E of which the length in the extension direction is long and the first vapor passage 51D of which the length in the extension direction is short extend in the same direction (second region A2), the width of the second vapor passage 51E of which the length in the extension direction is long is preferably wider than the width of the first vapor passage 51D of which the length in the extension direction is short in the region in which the vapor passages 51D, 51E extend in the same direction.

In the example shown in FIG. 22, as for the length of each of the plurality of second vapor passages 51E in the extension direction, the second vapor passage 51E disposed on the outer side in a direction orthogonal to the extension direction of the second vapor passage 51E (the right and left direction of FIG. 22, the short-side direction of the wick sheet 30) is longer. As for the length of each of the plurality of second vapor passages 51E in the extension direction, the second vapor passage 51E disposed on the inner side in the direction orthogonal to the extension direction of the second vapor passage 51E (the right and left direction of FIG. 22, the short-side direction of the wick sheet 30) is shorter. In this case, the second vapor passage 51E disposed on the outer side in a direction orthogonal to the extension direction of the second vapor passage 51E may have a wider width, and the second vapor passage 51E disposed on the inner side in the direction orthogonal to the extension direction of the second vapor passage 51E may have a narrower width. Thus, the width of the second vapor passage 51E that sends the working vapor 2a to a portion of which the distance from the heat source region SR is long can be widened to reduce the vapor resistance of the working vapor 2a flowing through the second vapor passage 51E. As a result, it is possible to achieve thermal uniformity in the entire region of the vapor chamber 1.

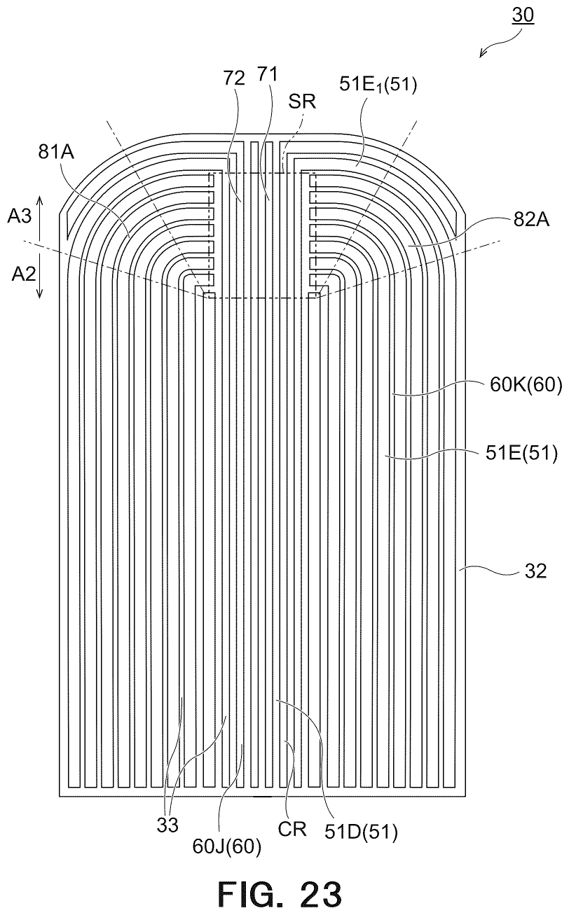

As shown in FIG. 23, each of the plurality of vapor passages 51 and the plurality of liquid channels 60 may extend over all the region in the circumferential direction about part of the region (heat source region SR). In FIG. 23, the second vapor passage indicated by the reference sign 51E₁ extends from the heat source region SR side to the opposite side from the condensation region CR, then bends at the vapor passage width change part 82A, and extends to the condensation region CR side.

According to the example shown in FIG. 23, even when the heat source region SR is separated from the frame 32, it is possible to cause the working vapor 2a to go around also in directions other than in a direction to the condensation region CR. Thus, it is possible to dissipate heat from the entire surface of the vapor chamber 1 or transfer heat to the entire surface of the vapor chamber 1.

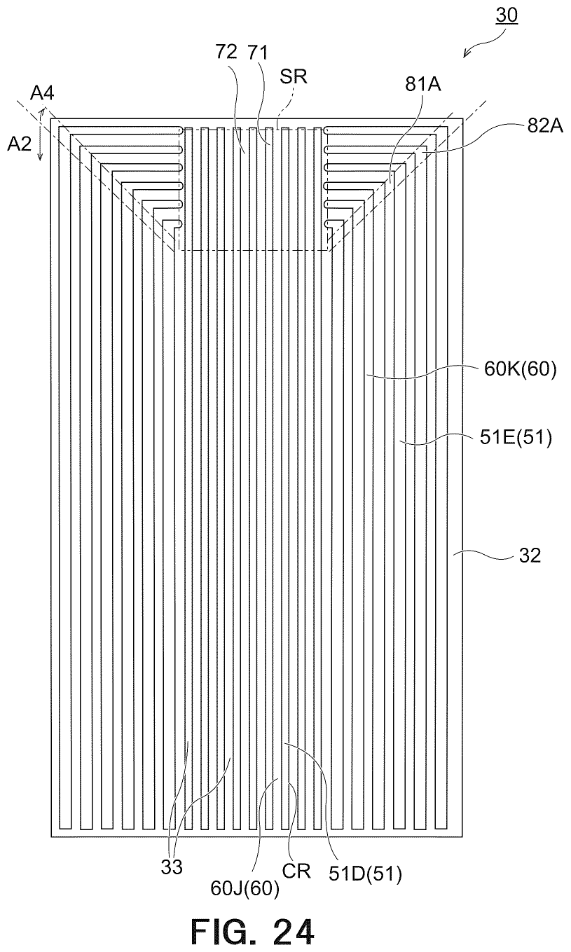

As shown in FIG. 24, the wick sheet 30 includes a fourth region A4 and a second region A2. The fourth region A4 is a region in which the vapor passages 51 and the liquid channels 60 extend so as to be bent. The second region A2 is a region in which the vapor passages 51 and the liquid channels 60 linearly extend in the same direction.

As shown in FIG. 24, the second vapor passage 51E is bent at a right angle at the vapor passage width change part 82A located in the fourth region A4. Similarly, the second liquid channel 60K is bent at a right angle at the liquid channel direction change part 81A located in the fourth region A4. The configuration is not limited thereto. Each of the second vapor passage 51E and the second liquid channel 60K may be bent at an acute angle or an obtuse angle in the fourth region A4.

In FIG. 24, the width of the second vapor passage 51E may also change in part in the extension direction of the second vapor passage 51E. Specifically, in the fourth region A4, the width of the second vapor passage 51E gradually widens from one side (heat source region SR side) toward the other side (condensation region CR side) in the extension direction of the second vapor passage 51E. In this case, the width of the second vapor passage 51E is wider at a portion located on the other side (condensation region CR side) in the extension direction of the second vapor passage 51E with respect to the vapor passage width change part 82A than at a portion located on one side (heat source region SR side) in the extension direction of the second vapor passage 51E with respect to the vapor passage width change part 82A. The width of the second vapor passage 51E at the first main body surface 31a may gradually widen from one side toward the other side in the extension direction of the second vapor passage 51E. Alternatively, the width of the second vapor passage 51E at the second main body surface 31b may gradually widen from one side toward the other side in the extension direction of the second vapor passage 51E. On the other hand, the width of the first vapor passage 51D may be uniform in the extension direction of the first vapor passage 51D. In the second vapor passage 51E, the width of a portion located on the other side in the extension direction of the second vapor passage 51E with respect to the vapor passage width change part 82A may be wider than the width of the first vapor passage 51D.

The width of the second liquid channel 60K may be uniform or may be changed in part in the extension direction of the second liquid channel 60K. When the width of the second liquid channel 60K varies, the width of the second liquid channel 60K may gradually widen from one side (heat source region SR side) toward the other side (condensation region CR side) in the extension direction of the second liquid channel 60K in the fourth region A4. In this case, the width of the second liquid channel 60K is wider at a portion located on the other side (condensation region CR side) in the extension direction with respect to the liquid channel direction change part 81A than at a portion located on one side (heat source region SR side) in the extension direction with respect to the liquid channel direction change part 81A. The width of the second liquid channel 60K at the first main body surface 31a may gradually widen from one side toward the other side in the extension direction of the second liquid channel 60K. Alternatively, the width of the second liquid channel 60K at the second main body surface 31b may gradually widen from one side toward the other side in the extension direction of the second liquid channel 60K. On the other hand, the width of the first liquid channel 60J may be uniform in the extension direction of the first liquid channel 60J. In the second liquid channel 60K, the width of a portion located on the other side in the extension direction of the second liquid channel 60K with respect to the liquid channel direction change part 81A may be wider than the width of the first liquid channel 60J.

According to the example shown in FIG. 24, it is possible to cause the working vapor 2a to go around to the corners of the vapor chamber 1. Thus, it is possible to dissipate heat from the entire surface of the vapor chamber 1 or transfer heat to the entire surface of the vapor chamber 1.

According to the example shown in FIGS. 23 and 24, the width of the second vapor passage 51E of which the length in the extension direction is long is wider than the width of the first vapor passage 51D of which the length in the extension direction is short. Thus, even when the distance from the heat source region SR is long, the vapor resistance of the working vapor 2a can be reduced. Therefore, the working vapor 2a can be quickly sent to the terminal end by using the second vapor passage 51E of which the length is long without delay from the working vapor 2a that passes through the first vapor passage 51D of which the length is short. Thus, even when the lengths of the plurality of vapor passages 51 are varied, it is possible to achieve thermal uniformity in the entire region of the vapor chamber 1.

### Eleventh Modification

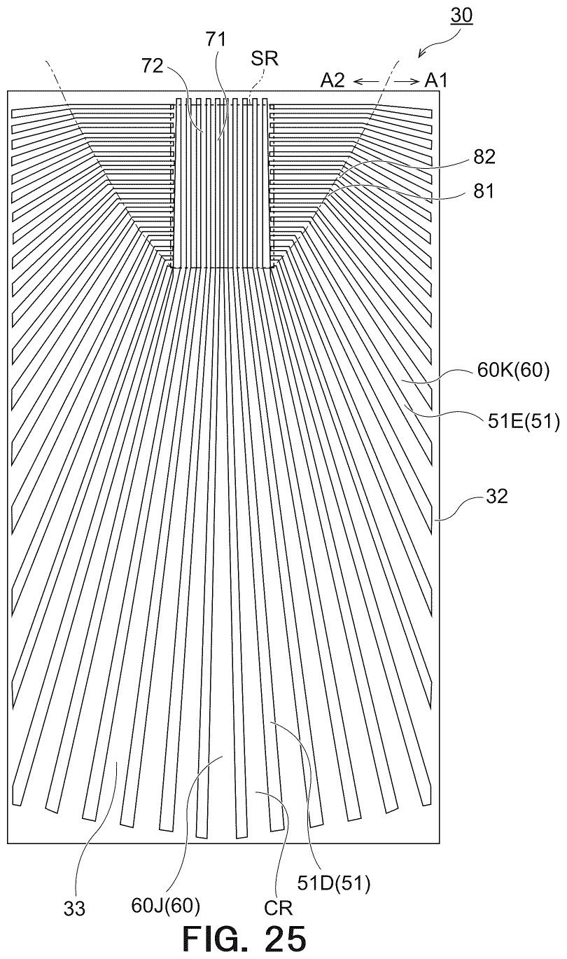

As shown in FIG. 25, the wick sheet 30 includes a first region A1 and a second region A2. The first region A1 is a region in which the vapor passages 51 and the liquid channels 60 radially extend. The second region A2 is a region in which the vapor passages 51 and the liquid channels 60 linearly extend in the same direction.

As shown in FIG. 25, the plurality of vapor passages 51 includes first vapor passages 51D and second vapor passages 51E. In the first region A1, the plurality of first vapor passages 51D radially extends from the heat source region SR. The plurality of second vapor passages 51E extends from the heat source region SR parallel to one another and is bent at the vapor passage direction change part 82. In the second vapor passage 51E, a portion located on the other side (condensation region CR side) in the extension direction of the second vapor passage 51E with respect to the vapor passage direction change part 82 radially extends. In the second vapor passage 51E, a portion located on the one side (heat source region SR side) in the extension direction of the second vapor passage 51E with respect to the vapor passage direction change part 82 is in the second region A2. In the second vapor passage 51E, a portion located on the other side in the extension direction of the second vapor passage 51E with respect to the vapor passage direction change part 82 is in the first region A1.

Similarly, the plurality of liquid channels 60 includes first liquid channels 60J and second liquid channels 60K. In the first region A1, the plurality of first liquid channels 60J radially extends from the heat source region SR. The plurality of second liquid channels 60K extends from the heat source region SR parallel to one another and is bent at the liquid channel direction change part 81. In the second liquid channel 60K, a portion located on one side (heat source region SR side) in the extension direction of the second liquid channel 60K with respect to the liquid channel direction change part 81 radially extends. In the second liquid channel 60K, a portion located on one side in the extension direction of the second liquid channel 60K with respect to the liquid channel direction change part 81 is present in the second region A2. In the second liquid channel 60K, a portion located on the other side (condensation region CR side) in the extension direction of the second liquid channel 60K with respect to the liquid channel direction change part 81 is present in the first region A1.

In FIG. 25, the width of the first vapor passage 51D is not uniform in the extension direction of the first vapor passage 51D and gradually widens from one side (heat source region SR side) toward the other side (condensation region CR side) in the extension direction of the first vapor passage 51D. The width of the first vapor passage 51D at the first main body surface 31a may gradually widen from one side toward the other side in the extension direction of the first vapor passage 51D. Alternatively, the width of the first vapor passage 51D at the second main body surface 31b may gradually widen from one side toward the other side in the extension direction of the first vapor passage 51D. In the second vapor passage 51E, the width of a portion located in the second region A2 is uniform in the extension direction of the second vapor passage 51E. In the second vapor passage 51E, the width of a portion located in the first region A1 gradually widens from one side toward the other side in the extension direction of the second vapor passage 51E. In the first region A1, the width of the second vapor passage 51E at the first main body surface 31a may gradually widen from one side toward the other side in the extension direction of the second vapor passage 51E. Alternatively, in the first region A1, the width of the second vapor passage 51E at the second main body surface 31b may gradually widen from one side toward the other side in the extension direction of the second vapor passage 51E.

The width of the first liquid channel 60J gradually widens from one side (heat source region SR side) toward the other side (condensation region CR side) in the extension direction of the first liquid channel 60J. The width of the first liquid channel 60J at the first main body surface 31a may gradually widen from one side toward the other side in the extension direction of the first liquid channel 60J. Alternatively, the width of the first liquid channel 60J at the second main body surface 31b may gradually widen from one side toward the other side in the extension direction of the first liquid channel 60J. In the second liquid channel 60K, the width of a portion located in the second region A2 is uniform in the extension direction of the second liquid channel 60K. In the second liquid channel 60K, the width of a portion located in the first region A1 gradually widens from one side (heat source region SR side) toward the other side (condensation region CR side) in the extension direction of the second liquid channel 60K. In the first region A1, the width of the second liquid channel 60K at the first main body surface 31a may gradually widen from one side toward the other side in the extension direction of the second liquid channel 60K. Alternatively, in the first region A1, the width of the second liquid channel 60K at the second main body surface 31b may gradually widen from one side toward the other side in the extension direction of the second liquid channel 60K.

According to the example shown in FIG. 25, it is possible to cause the working vapor 2a to go around to the corners of the vapor chamber 1. Since the vapor resistance at the terminal end of the vapor passage 51 is reduced, it is possible to quickly convey the working vapor 2a to the terminal end of the vapor passage 51. Thus, it is possible to suppress a decrease in heat transfer performance. It is possible to dissipate heat from the entire surface of the vapor chamber 1 or transfer heat to the entire surface of the vapor chamber 1.

The present disclosure is not limited to the embodiment and the modifications, and component elements may be modified without departing from the purport of the present disclosure. Various inventions may be provided by appropriate combinations of the plurality of component elements described in the embodiment and the modifications. Some component elements may be deleted from all the component elements described in the embodiment and the modifications.

1-21. (canceled)

22. A wick sheet for a vapor chamber, the wick sheet comprising:
a plurality of vapor passages through which vapor of a working fluid passes; and
a plurality of liquid channels through which liquid of the working fluid passes, wherein
widths of the plurality of vapor passages are different from each other, and
the width of the vapor passage of which a length in an extension direction is long is wider than the width of the vapor passage of which a length in an extension direction is short.

23. The wick sheet according to claim 22, wherein
the width of the vapor passage changes at a width change part midway in the extension direction of the vapor passage, and
the width of the vapor passage is uniform on each of one side of the width change part and the other side of the width change part in the extension direction of the vapor passage.

24. The wick sheet according to claim 22, wherein the lengths of the plurality of vapor passages in the respectively extension directions are different from each other, and the width of the vapor passage widens as the length of the vapor passage in the extension direction increases.

25. The wick sheet according to claim 22, wherein a width of the vapor passage changes at a width change part midway in an extension direction of the vapor passage, and
the width of the vapor passage is uniform on one side of the width change part and gradually widens on the other side of the width change part in the extension direction of the vapor passage.

26. A vapor chamber filled with a working fluid, the vapor chamber comprising:
at least one sheet; and
the wick sheet according to claim 22, laminated on the sheet.

27. An electronic apparatus comprising:
a housing;
a heat source accommodated in the housing; and
the vapor chamber according to claim 26, being in thermal contact with the heat source.

28. A wick sheet for a vapor chamber, the wick sheet comprising:
a first main body surface;
a second main body surface on an opposite side to the first main body surface;
a plurality of vapor passages through which vapor of a working fluid passes; and
a plurality of liquid channels through which liquid of the working fluid passes, wherein
widths of the plurality of vapor passages at the first main body surface are different from each other or widths of the plurality of vapor passages at the second main body surface are different from each other, and
the width of the vapor passage at the first main body surface, of which a length in an extension direction is long, is wider than the width of the vapor passage at the first main body surface, of which the length in an extension direction is short, or the width of the vapor passage at the second main body surface, of which a length in an extension direction is long, is wider than the width of the vapor passage at the second main body surface, of which the length in an extension direction is short.

29. The wick sheet according to claim 28, wherein
the width of the vapor passage at the first main body surface or the width of the vapor passage at the second main body surface changes at a width change part midway in the extension direction of the vapor passage, and
the width of the vapor passage at the first main body surface or the width of the vapor passage at the second main body surface is uniform on each of one side of the width change part and the other side of the width change part in the extension direction of the vapor passage.

30. The wick sheet according to claim 28, wherein the lengths of the plurality of vapor passages in the respectively extension directions are different from each other, and the width of the vapor passage at the first main body surface or the width of the vapor passage at the second main body surface widens as the length of the vapor passage in the extension direction increases.

31. The wick sheet according to claim 28, wherein
the width of the vapor passage at the first main body surface or the width of the vapor passage at the second main body surface changes at a width change part midway in an extension direction of the vapor passage, and
the width of the vapor passage at the first main body surface or the width of the vapor passage at the second main body surface is uniform on one side of the width change part and gradually widens on the other side of the width change part in the extension direction of the vapor passage.

32. A vapor chamber filled with a working fluid, the vapor chamber comprising:
at least one sheet; and
the wick sheet according to claim 28, laminated on the sheet.

33. An electronic apparatus comprising:
a housing;
a heat source accommodated in the housing; and
the vapor chamber according to claim 32, being in thermal contact with the heat source.

34. A wick sheet for a vapor chamber, the wick sheet comprising:
a plurality of vapor passages through which vapor of a working fluid passes; and
a plurality of liquid channels through which liquid of the working fluid passes, wherein
there are a region in which the vapor passages and the liquid channels extend so as to be curved or bent and
a region in which the vapor passages and the liquid channels linearly extend in the same direction, and
in the region in which the vapor passages and the liquid channels extend so as to be curved or bent, a width of the vapor passage gradually widens from one side toward the other side in an extension direction of the vapor passage or a width of the liquid channel gradually widens from one side toward the other side in an extension direction of the liquid channel.

35. A vapor chamber filled with a working fluid, the vapor chamber comprising:
at least one sheet; and
the wick sheet according to claim 34, laminated on the sheet.

36. An electronic apparatus comprising:
a housing;
a heat source accommodated in the housing; and
the vapor chamber according to claim 35, being in thermal contact with the heat source.

37. A wick sheet for a vapor chamber, the wick sheet comprising:
a first main body surface;
a second main body surface on an opposite side to the first main body surface;
a plurality of vapor passages through which vapor of a working fluid passes; and
a plurality of liquid channels through which liquid of the working fluid passes, wherein
there are a region in which the vapor passages and the liquid channels extend so as to be curved or bent and
a region in which the vapor passages and the liquid channels linearly extend in the same direction, and
in the region in which the vapor passages and the liquid channels extend so as to be curved or bent, a width of the vapor passage at the first main body surface or the second main body surface gradually widens from one side toward the other side in an extension direction of the vapor passage or a width of the liquid channel at the first main body surface or the second main body surface gradually widens from one side toward the other side in an extension direction of the liquid channel.

38. A vapor chamber filled with a working fluid, the vapor chamber comprising:
at least one sheet; and
the wick sheet according to claim 37, laminated on the sheet.

39. An electronic apparatus comprising:
a housing;
a heat source accommodated in the housing; and
the vapor chamber according to claim 38, being in thermal contact with the heat source.
